(19) United States
(12) Patent Application Publication
(10) Pub. No.: US 2013/0214427 A1
(43) Pub. Date: Aug. 22, 2013

(54) SEMICONDUCTOR DEVICE HAVING PLURAL SEMICONDUCTOR CHIPS STACKED WITH EACH OTHER

(71) Applicant: Elpida Memory, Inc., (US)

(72) Inventor: Yusuke NAKANOYA, Tokyo (JP)

(73) Assignee: ELPIDA MEMORY, INC., Tokyo (JP)

(21) Appl. No.: 13/764,235

(22) Filed: Feb. 11, 2013

(30) Foreign Application Priority Data
Feb. 16, 2012 (JP) 2012-031901

(51) Int. Cl. H01L 23/538

(52) U.S. Cl. CPC H01L 23/5384
USPC 257/774

(57) ABSTRACT

A first semiconductor chip includes a first surface and a second surface opposite to the first surface. A second semiconductor chip is stacked over the second surface of the first semiconductor chip. The second semiconductor chip is larger in size than the first semiconductor chip. A first sealing resin covers the first and second semiconductor chips so that the first surface exposes from the first sealing resin. A first width of the first sealing resin that is around the first semiconductor chip is larger than a second width of the first sealing resin that is around the second semiconductor chip.

### BACKGROUND OF THE INVENTION

1. Field of the Invention

The present invention relates to a method for manufacturing a semiconductor device, and more particularly to a method for manufacturing a semiconductor device that includes a plurality of stacked semiconductor chips.

2. Description of Related Art

Japanese Patent Application Laid-Open No. 2010-251347 discloses a method for manufacturing a chip-on-chip (CoC) type semiconductor device. The method includes stacking a plurality of semiconductor chips to form a chip stacked body, filling an underfill material into between the semiconductor chips by a capillary action, and then mounting the chip stacked body on a wiring substrate.

Suppose that a plurality of semiconductor chips having different chip sizes are used to form a chip stacked body. According to the method for manufacturing a semiconductor device described in Japanese Patent Application Laid-Open No. 2010-251347, gaps between the semiconductor chips cannot be adequately filled with the underfill material by a single filling operation using the capillary action. Since a plurality of separate filling operations with the underfill material are needed, the manufacturing processes of the semiconductor device become complicated.

Take, for example, a semiconductor chip that includes bump electrodes to be electrically connected to connection pads of a wiring substrate and has an external size smaller than that of the other semiconductor chips. To arrange such a small semiconductor chip at the uppermost layer (the lowermost layer when mounted), the process for filling the gap between the semiconductor chips with the underfill material needs to include a first step of filling gaps between the other semiconductor chips with the underfill material and a second step of filling a gap between the small semiconductor chip arranged at the uppermost layer and another semiconductor chip arranged immediately below the small semiconductor chip with the underfill material. In such a case, the underfill material needs to be filled in two separate operations.

If the semiconductor chip arranged at the uppermost layer is a thinned one (50 μm or less in thickness), the underfill material may run over the small semiconductor chip at the uppermost layer and adhere to the bump electrodes in the foregoing second step because of the extremely small thickness of the semiconductor chip.

If the underfill material thus adheres to the bump electrodes, the electrical connection reliability between the chip stacked body and a wiring substrate drops when the chip stacked body is mounted on the wiring substrate.

### SUMMARY

In one embodiment, there is provided a semiconductor device that includes: a first semiconductor chip including a first surface and a second surface opposite to the first surface; a second semiconductor chip stacked over the second surface of the first semiconductor chip, and the second semiconductor chip being larger in size than the first semiconductor chip; and a first sealing resin covering the first and second semiconductor chips so that the first surface exposes from the first sealing resin. A first width of the first sealing resin that is around the first semiconductor chip is larger than a second width of the first sealing resin that is around the second semiconductor chip.

In another embodiment, there is provided a semiconductor device that includes: a first sealing resin having a substantially trapezoidal shape in side view; a first semiconductor chip including a first surface and a second surface opposite to the first surface, the first semiconductor chip being embedded in the first sealing resin so that the first surface exposes from a longer side of the substantially trapezoidal shape of the first sealing resin; and a second semiconductor chip stacked over the second surface of the first semiconductor chip and embedded in the first sealing resin, and the second semiconductor chip is larger in size than the first semiconductor chip.

In still another embodiment, there is provided a semiconductor device that includes: a first semiconductor chip including a first surface and a second surface opposite to the first surface; a second semiconductor chip stacked over the second surface of the first semiconductor chip, and the second semiconductor chip being larger in size than the first semiconductor chip; and a sealing resin covering the first and second semiconductor chips, the sealing resin including a bottom surface exposing the first surface of the semiconductor chip, a total area including an area of the first surface of the first semiconductor chip and an area of the bottom surface of the sealing resin, and the total area is larger in area than the second semiconductor chip.

According to the present inventions, the chip stacked body may be pasted so that the one surface of the third semiconductor chip having an external size smaller than that of the first and second semiconductor chips may be in contact with the adhesive layer. The second semiconductor chip and the adhesive layer can thus create therebetween a gap where the semi-cured underfill material can flow by a capillary action.

This can reduce the number of filling operations of the underfill material, which conventionally needs to be two, to one. The steps for manufacturing the semiconductor device can thus be simplified.

The single filling operation of the underfill material can also reduce the heat load on the chip stacked body in the underfill material filling step.

The semi-cured underfill material may be supplied after the chip stacked body is pasted so that the one surface of the third semiconductor chip is in contact with the adhesive layer. The underfill material can be thus prevented from adhering to the one surface of the third semiconductor chip.

This can improve the electrical connection reliability between the wiring substrate and the chip stacked body when the chip stacked body having the first sealing resin is mounted on the wiring substrate.

### BRIEF DESCRIPTION OF THE DRAWINGS

FIG. 1 is a sectional view of a semiconductor device according to a first embodiment of the present invention;

FIG. 2 is a sectional view showing manufacturing process (1) of a semiconductor device according to a first embodiment of the present invention;

FIG. 3 is a sectional view showing manufacturing process (2) of a semiconductor device according to a first embodiment of the present invention;

FIG. 4 is a sectional view showing manufacturing process (3) of a semiconductor device according to a first embodiment of the present invention;

FIG. 5 is a sectional view showing manufacturing process (4) of a semiconductor device according to a first embodiment of the present invention;

FIG. 6 is a sectional view showing manufacturing process (5) of a semiconductor device according to a first embodiment of the present invention;

FIG. 7 is a sectional view showing manufacturing process (6) of a semiconductor device according to a first embodiment of the present invention;

FIG. 8 is a sectional view showing manufacturing process (7) of a semiconductor device according to a first embodiment of the present invention;

FIG. 9 is a sectional view showing manufacturing process (8) of a semiconductor device according to a first embodiment of the present invention;

FIG. 10 is a sectional view showing manufacturing process (9) of a semiconductor device according to a first embodiment of the present invention;

FIG. 11 is a sectional view showing manufacturing process (10) of a semiconductor device according to a first embodiment of the present invention;

FIG. 12 is a sectional view showing manufacturing process (11) of a semiconductor device according to a first embodiment of the present invention;

FIG. 13 is a sectional view showing manufacturing process (12) of a semiconductor device according to a first embodiment of the present invention;

FIG. 14 is a sectional view showing manufacturing process (13) of a semiconductor device according to a first embodiment of the present invention;

FIG. 15 is a sectional view showing manufacturing process (14) of a semiconductor device according to a first embodiment of the present invention;

FIG. 16 is a sectional view showing manufacturing process (15) of a semiconductor device according to a first embodiment of the present invention;

FIG. 17 is a sectional view showing manufacturing process (16) of a semiconductor device according to a first embodiment of the present invention;

FIG. 18 is a sectional view showing manufacturing process (17) of a semiconductor device according to a first embodiment of the present invention;

FIG. 19 is a sectional view of a semiconductor device according to a second embodiment of the present invention; and

FIGS. 20A and 20B are plan views of the second and third semiconductor chips, respectively.

### DETAILED DESCRIPTION OF THE EMBODIMENTS

Hereinafter, with reference to the accompanying drawings, embodiments of the present invention will be described in detail. Incidentally, the drawings used in the following description are for illustrating the configurations of the embodiments of the present invention. The size, thickness, dimensions, and other factors of each of the sections shown in the drawings may be different from the dimensional relationship of an actual semiconductor device. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

### First Embodiment

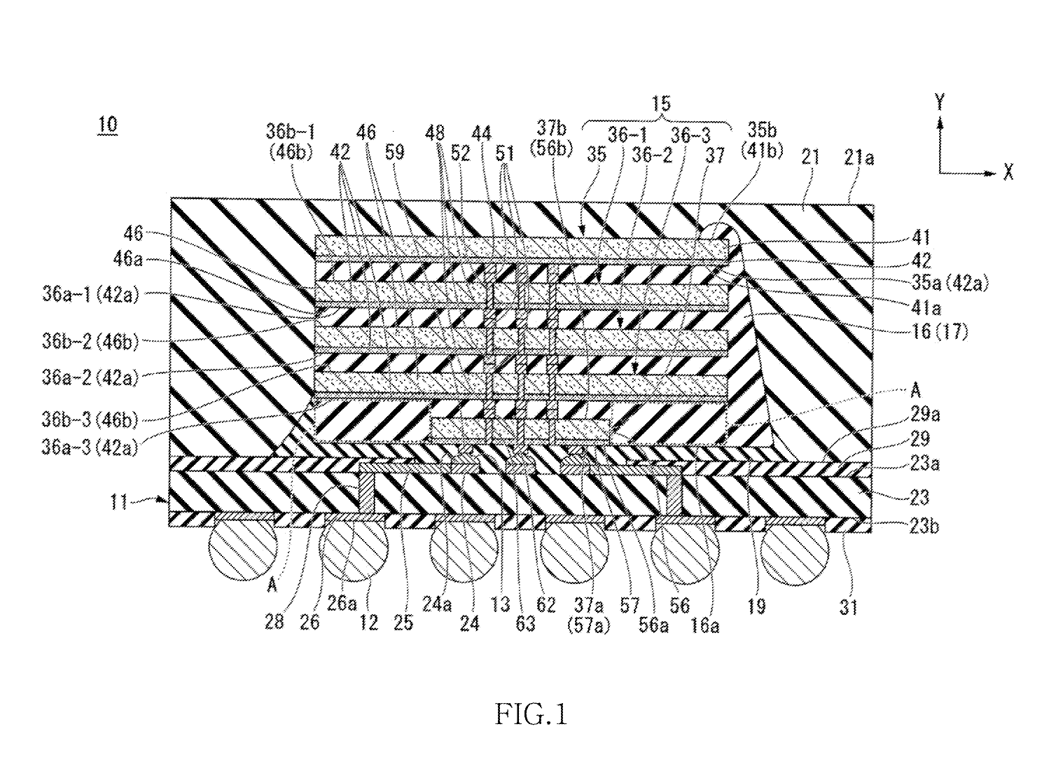

A configuration of a semiconductor device 10 according to the first embodiment of the present invention will be explained with reference to FIG. 1. The X direction shown in FIG. 1 represents a plane direction parallel to one surfaces 35a, 36a-1, 36a-2, 36a-3, and 37a of first to third semiconductor chips 35, 36-1, 36-2, 36-3, and 37. The Y direction represents a direction orthogonal to the X direction.

In FIG. 1, a description will be given below by using a CoC type semiconductor device as an example of the semiconductor device 10 according to the first embodiment.

Referring to FIG. 1, the semiconductor device 10 according to the first embodiment includes a wiring substrate 11, external connection terminals 12, wire bumps 13, a chip stacked body 15, a first sealing resin 16, an adhesive member 19, and a second sealing resin 21.

The wiring substrate 11 includes a substrate body 23, connection pads 24, wiring 25, lands 26, through electrodes 28, a first solder resist 29, and a second solder resist 31.

The substrate body 23 is an insulating substrate having a rectangular planar shape. For example, a glass epoxy substrate may be used as the substrate body 23.

The connection pads 24 are formed on one surface 23a of the substrate body 23 (one surface of the wiring substrate 11). The connection pads 24 are arranged in the center area of the one surface 23a of the substrate body 23. The connection pads 24 have bump forming surfaces 24a on which the wire bumps 13 are arranged.

The wiring 25 is formed on the one surface 23a of the substrate body 23. The wiring 25 is integrally formed with the connection pads 24. The wiring 25 is thereby electrically connected to the connection pads 24. The wiring 25 functions as rewiring.

The lands 26 are formed on the other surface 23b of the substrate body 23. The lands 26 have terminal mounting surfaces 26a on which the external connection terminals 12 are mounted.

The through electrodes 28 are formed to run through the substrate body 23 at positions between the wiring 25 and the lands 26. The through electrodes 28 are connected at one ends to the wiring 25, and at the other ends to the lands 26. The through electrodes 28 thereby electrically connect the connection pads 24 and the lands 26.

The first solder resist 29 is formed on the one surface 23a of the substrate body 23 so as to expose the bump forming surfaces 24a and cover a part of the wiring 25.

The second solder resist 31 is formed on the other surface 23b of the substrate body 23 so as to expose the terminal mounting surfaces 26a.

The external connection terminals 12 are mounted on the terminal mounting surfaces 26a of the lands 26. For example, solder balls may be used as the external connection terminals 12.

The wire bumps 13 are formed on the bump forming surfaces 24a of the connection pads 24. The wire bumps 13 may be made of such materials as Au and Cu.

The chip stacked body 15 includes one first semiconductor chip 35, three second semiconductor chips 36-1, 36-2, and 36-3, and one third semiconductor chip 37.

The first semiconductor chip 35 is a semiconductor chip to be arranged at the uppermost layer when the chip stacked body 15 is mounted on the wiring substrate 11.

The first semiconductor chip 35 is a thinned semiconductor chip (for example, around 100 μm in thickness) having a rectangular planar shape. The first semiconductor chip 35 includes a semiconductor substrate 41, a circuit element layer 42, and first bump electrodes 44 (surface bump electrodes).

For example, a semiconductor memory device may be used as the first semiconductor chip 35. The following description of the first embodiment deals with an example where a semiconductor memory device is used as the first semiconductor chip 35.

The semiconductor substrate 41 is a substrate having a rectangular planar shape. For example, a monocrystalline silicon substrate may be used as the semiconductor substrate 41.

The circuit element layer 42 is formed on the surface 41a of the semiconductor substrate 41. The circuit element layer 42 has a multilayer wiring structure, and includes circuit elements (not shown) having a memory function.

The first bump electrodes 44 are formed on the one surface 35a of the first semiconductor chip 35 (the surface 42a of the circuit element layer 42). The first bump electrodes 44 are arranged in the center area of the one surface 35a of the first semiconductor chip 35. The first bump electrodes 44 are electrically connected to the circuit elements (not shown) formed on the circuit element layer 42.

The other surface 35b of the first semiconductor chip 35 (the backside 41b of the semiconductor substrate 41) is a flat surface without a bump electrode (backside bump electrode).

The first semiconductor chip 35 is arranged above the semiconductor substrate 11 so that the one surface 35a of the first semiconductor chip 35 where the first bump electrodes 44 are arranged faces to the one surface 23a of the substrate body 23.

As described above, the first semiconductor chip 35 is not provided with a backside bump electrode or a through electrode. The first semiconductor chip 35 can thus be made thicker than the second and third semiconductor chips 36-1, 36-2, 36-3, and 37 which have through electrodes 52 and 63 to be described later.

Specifically, if the second and third semiconductor chips 36-1, 36-2, 36-3, and 37 are 50 μm in thickness, the first semiconductor chip 35 may have a thickness of 100 μm, for example.

Since the first semiconductor chip 35 lying the farthest from the wiring substrate 11 when the chip stacked body 15 is mounted on the wiring substrate 11 has an increased thickness, a stress due to heating after the mounting of the chip stacked body 15 can be reduced. This can suppress breakage of the chip stacked body 15.

The second semiconductor chip 36-1 is a semiconductor chip of rectangular planar shape, made thinner than the first semiconductor chip 35 (for example, 50 μm or less in thickness). The second semiconductor chip 36-1 has the same size (external size) as that of the first semiconductor chip 35 in the X direction.

For example, a semiconductor memory device may be used as the second semiconductor chip 36-1. The following description of the first embodiment deals with an example where a semiconductor memory device is used as the second semiconductor chip 36-1.

The second semiconductor chip 36-1 has the same configuration as that of the first semiconductor chip 35 except that a semiconductor substrate 46, second bump electrodes 48 (surface bump electrodes), third bump electrodes 51 (backside bump electrodes), and through electrodes 52 are formed instead of the semiconductor substrate 41 and the first bump electrodes 44 of the first semiconductor chip 35.

The semiconductor substrate 46 has the same configuration as that of the semiconductor substrate 41 except being thinner than the semiconductor substrate 41. The circuit element layer 42 is formed on the surface 46a of the semiconductor substrate 46.

The second bump electrodes 48 are formed on the one surface 36a-1 of the second semiconductor chip 36-1 (the surface 42a of the circuit element layer 42). The second bump electrodes 48 are arranged in the center area of the one surface 36a-1 of the second semiconductor chip 36-1 so as to be opposed to the third bump electrodes 51. In other words, the second bump electrodes 48 are arranged in the same layout as that of the third bump electrodes 51.

The third bump electrodes 51 are formed on the other surface 36b-1 of the second semiconductor chip 36-1 (the backside 46b of the semiconductor substrate 46). The second bump electrodes 48 are arranged in the center area of the one surface 36a-1 of the second semiconductor chip 36-1 so as to be opposed to the first bump electrodes 44. In other words, the third bump electrodes 51 are arranged in the same layout as that of the first bump electrodes 44.

The through electrodes 52 are formed to run through the semiconductor substrate 46 and the circuit element layer 42 at positions between the second bump electrodes 48 and the third bump electrodes 51. The through electrodes 52 are connected at one ends to the second bump electrodes 48 and at the other ends to the third bump electrodes 51. The through electrodes 52 thereby electrically connect the second bump electrodes 48 and the third bump electrodes 51.

The second semiconductor chip 36-1 is arranged directly below the first semiconductor chip 35 lying at the uppermost layer so that the other surface 36b-1 of the second semiconductor chip 36-1 (the backside 46b of the semiconductor substrate 46) is opposed to the one surface 35a of the first semiconductor chip 35 when the chip stacked body 15 is mounted on the wiring substrate 11.

The third bump electrodes 51 of the second semiconductor chip 36-1 are joined (electrically connected) to the first bump electrodes 44 of the first semiconductor chip 35. The second semiconductor chip 36-1 is thereby flip-chip connected to the first semiconductor chip 35.

The second semiconductor chips 36-2 and 36-3 have the same configuration as that of the second semiconductor chip 36-1.

The second semiconductor chip 36-2 is arranged immediately below the second semiconductor chip 36-1 so that the other surface 36b-2 of the second semiconductor chip 36-2 (the backside 46b of the semiconductor substrate 46) is opposed to the one surface 36a-1 of the second semiconductor chip 36-1 when the chip stacked body 15 is mounted on the wiring substrate 11.

The third bump electrodes 51 of the second semiconductor chip 36-2 are joined (electrically connected) to the second bump electrodes 48 of the second semiconductor chip 36-1. The second semiconductor chip 36-2 is thereby flip-chip connected to the second semiconductor chip 36-1.

The second semiconductor chip 36-3 is arranged immediately below the second semiconductor chip 36-2 so that the other surface 36b-3 of the second semiconductor chip 36-3 (the backside 46b of the semiconductor substrate 46) is opposed to the one surface 36a-2 of the second semiconductor chip 36-2 when the chip stacked body 15 is mounted on the wiring substrate 11.

The third bump electrodes 51 of the second semiconductor chip 36-3 are joined (electrically connected) to the second bump electrodes 48 of the second semiconductor chip 36-2. The second semiconductor chip 36-3 is thereby flip-chip connected to the second semiconductor chip 36-2.

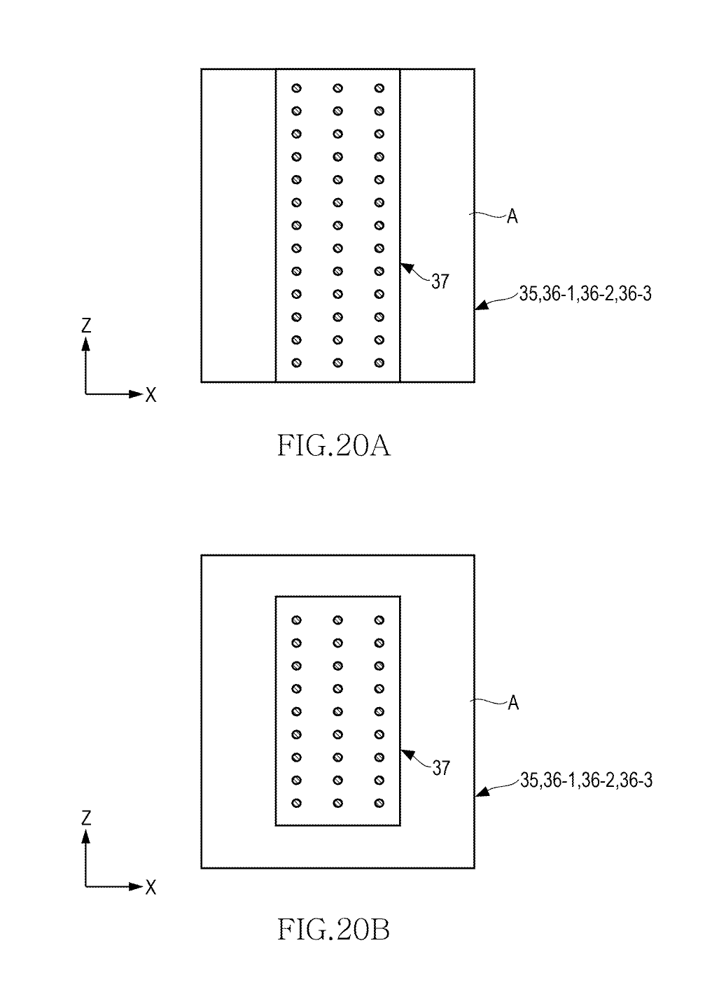

The third semiconductor chip 37 is a rectangular semiconductor chip made thinner than the first semiconductor chip 35 (for example, 50 μm or less in thickness). As shown in FIG. 20A, the third semiconductor chip 37 has a size (external size) smaller than that of the first and second semiconductor chips 35, 36-1, 36-2, and 36-3 in the X direction. As shown in FIG. 20B, a semiconductor chip having a smaller size than that of the first and second semiconductor chips in the X and Z directions may be used as the third semiconductor chip 37.

For example, a control chip having an interface function may be used as the third semiconductor chip 37. The following description of the first embodiment deals with an example where a control chip having an interface function is used as the third semiconductor chip 37.

The third semiconductor chip 37 is a semiconductor chip to be arranged at the lowermost layer when the chip stacked body 15 is mounted on the wiring substrate 11.

The third semiconductor chip 37 is a thinned semiconductor chip (for example, 50 μm or less in thickness) having a rectangular planar shape. The third semiconductor chip 37 includes a semiconductor substrate 56, a circuit element layer 57, fourth bump electrodes 59 (surface bump electrodes), fifth bump electrodes 62 (backside bump electrodes), and through electrodes 63.

The semiconductor substrate 56 is a substrate having a rectangular planar shape. The semiconductor substrate 56 is smaller than the semiconductor substrate 41 or 46 in X direction. For example, a monocrystalline silicon substrate may be used as the semiconductor substrate 56.

The circuit element layer 57 is formed on the surface 56a of the semiconductor substrate 56. The circuit element layer 57 has a multilayer wiring structure, and includes circuit elements (not shown) having an interface function.

The third semiconductor chip 37 is arranged immediately below the second semiconductor chip 36-3 so that the other surface 37b of the third semiconductor chip 37 (the backside 56b of the semiconductor substrate 56) is opposed to the one surface 36a-3 of the second semiconductor chip 36-3 when the chip stacked body 15 is mounted on the wiring substrate 11.

The third semiconductor chip 37 is arranged on the center area of the second semiconductor chip 36-3. As shown in FIG. 20A, the short sides of the third semiconductor chip 37 are positioned to overlap those of the first and second semiconductor chips 35, 36-1, 36-2, and 36-3.

The peripheral areas around the third semiconductor chip 37 include portions that are opposed to the one surface 36a-3 of the second semiconductor chip 36-3. Such portions form chip non-mounting areas A where the third semiconductor chip 37 is not mounted.

The fourth bump electrodes 59 are formed on the one surface 37a of the third semiconductor chip 37 (the surface 57a of the circuit element layer 57). The fourth bump electrodes 59 are arranged on the one surface 37a of the third semiconductor chip 37 so as to be opposed to the connection pads 24 formed on the wiring layer 11. The fourth bump electrodes 59 are electrodes that function as external connection terminals of the chip stacked body 15. The fourth bump electrodes 59 are electrically connected to the connection pads 24 through the wire bumps 13. The chip stacked body 15 is thereby flip-chip mounted on the wiring substrate 11.

The fifth bump electrodes 62 are formed on the other surface 37b of the third semiconductor chip 37 (the surface 56b of the semiconductor substrate 56). The fifth bump electrodes 62 are arranged so as to be opposed to the second bump electrodes 48 of the second semiconductor chip 36-3. In other words, the fifth bump electrodes 62 are arranged in the same layout as that of the second bump electrodes 48 of the second semiconductor chip 36-3.

The fifth bump electrodes 62 are joined (electrically connected) to the second bump electrodes 48 of the second semiconductor chip 36-3. The third semiconductor chip 37 is thereby electrically connected to the first and second semiconductor chips 35, 36-1, 36-2 and 36-3.

The through electrodes 63 are formed to run through the semiconductor substrate 56 and the circuit element layer 57. The through electrodes 63 are connected at one ends to the fifth bump electrodes 62. The through electrodes 63 thereby electrically connect the fourth bump electrodes 59 via wirings which is not shown in FIG. 1.

The first sealing resin 16 is made of a fully-cured underfill material 17. The first sealing resin 16 is formed to fill gaps between the first semiconductor chip 35 and the second semiconductor chip 36-1, between the second semiconductor chip 36-1 and the second semiconductor chip 36-2, between the second semiconductor chip 36-2 and the second semiconductor chip 36-3, and between the second semiconductor chip 36-3 and the third semiconductor chip 37.

The first sealing resin 16 is also formed in the chip non-mounting areas A. The first sealing resin 16 arranged in the chip non-mounting areas A covers the sidewalls of the third semiconductor chip 37 and covers the one surface 36a-3 of the second semiconductor chip 36-3 lying in the chip non-mounting areas A.

The first sealing resin 16 has a flat bottom surface 16a. The bottom surface 16a is generally flush with the one surface 37a of the third semiconductor chip 37.

The adhesive member 19 is arranged to fill gaps between the wiring substrate 11 and the third semiconductor chip 37 and between the wiring substrate 11 and the bottom surface 16a of the first sealing resin 16. The adhesive member 19 seals the fourth bump electrodes 59, the wire bumps 13, and the connection pads 24.

For example, a non-conductive paste (NCP) may be used as the adhesive member 19.

The second sealing resin 21 is formed on the top surface 29a of the first solder resist 29 so as to seal the chip stacked body 15, the first sealing resin 16, and the adhesive member 19. The second sealing resin 21 has a flat top surface 21a. For example, molded resin may be used as the second sealing resin 21.

According to the semiconductor device of the first embodiment, the first sealing resin 16 is formed in the chip non-mounting areas A around the third semiconductor chip 37. The adhesive member 19 is formed to fill the gaps between the one surface 37a of the third semiconductor chip 37 and the wiring substrate 11 and between the bottom surface 16a of the sealing resin 16 and the wiring substrate 11. Such a configuration increases the adhesion area between the chip stacked body 15 having the first sealing resin 16 and the adhesive member 19 on the side of the one surface 37a of the third semiconductor chip 37. Even when an external force is applied to the chip stacked body 15, a stress applied to the fourth bump electrodes 59 is thus reduced. This can improve the electrical connection reliability between the chip stacked body 15 and the wiring substrate 11.

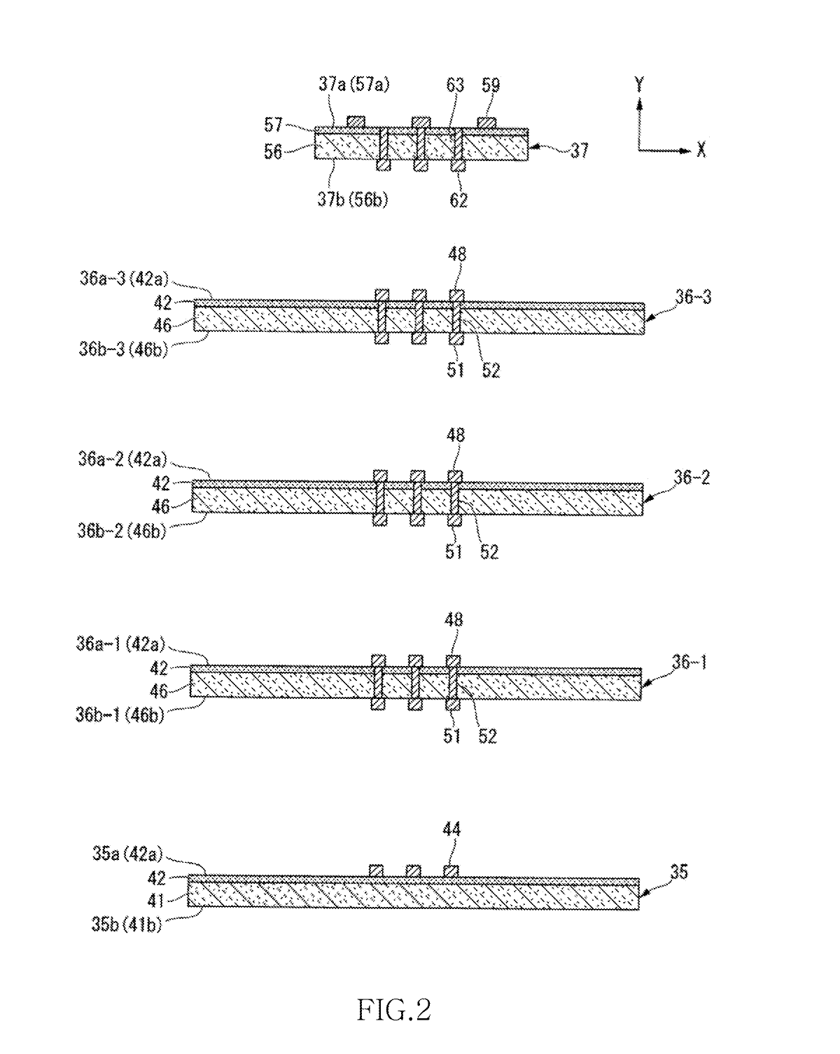

FIGS. 2 to 18 are sectional views showing steps for manufacturing a semiconductor device according to the first embodiment of the present invention. In FIGS. 2 to 18, the same components as those of the semiconductor device 10 according to the first embodiment are designated by the same reference symbols.

A method for manufacturing a semiconductor device according to the first embodiment will be described with reference to FIGS. 2 to 18.

Initially, in the step shown in FIG. 2, the following first to third semiconductor chips 35, 36-1, 36-2, 36-3, and 37 are prepared. The first semiconductor chip 35 includes first bump electrodes 44 arranged on one surface 35a. The other surface 35b having no bump electrode. The second semiconductor chip 36-1 has the same size as that of the first semiconductor chip 35, and includes second bump electrodes 48 arranged on one surface 36a-1 and third bump electrodes arranged on the other surface 36b-1. The second semiconductor chip 36-2 has the same size as that of the first semiconductor chip 35, and includes second bump electrodes 48 arranged on one surface 36a-2 and third bump electrodes arranged on the other surface 36b-2. The second semiconductor chip 36-3 has the same size as that of the first semiconductor chip 35, and includes second bump electrodes 48 arranged on one surface 36a-3 and third bump electrodes arranged on the other surface 36b-3. The third semiconductor chip 37 has an outer shape smaller than that of the first and second semiconductor chips 35, 36-1, 36-2, and 36-3, and includes fourth bump electrodes 59 arranged on one surface 37a and fifth bump electrodes 62 arranged on the other surface 37b.

The first to third semiconductor chips 35, 36-1, 36-2, 36-3, and 37 are thinned semiconductor chips.

The following description of the first embodiment deals with an example where semiconductor memory devices are used as the first and second semiconductor chips 35, 36-1, 36-2, and 36-3, and a control chip having an interface surface is used as the third semiconductor chip 37 in the step shown in FIG. 2.

In the step shown in FIG. 2, the first semiconductor chip 35, which is arranged at the uppermost layer (in other words, in a position farthest from the wiring substrate 11) when the chip stacked body 15 is mounted on the wiring substrate 11 as shown in FIG. 1, may be thicker than the second and third semiconductor chips 36-1, 36-2, 36-3, and 37. Specifically, if the second and third semiconductor chips 36-1, 36-2, 36-3, and 37 are 50 μm in thickness, the first semiconductor chip 35 may have a thickness of 100 μm, for example.

Since the first semiconductor chip 35 lying the farthest from the wiring substrate 11 when the chip stacked body 15 is mounted on the wiring substrate 11 has an increased thickness, a stress due to heating after the mounting of the chip stacked body 15 can be reduced. This can suppress breakage of the chip stacked body 15.

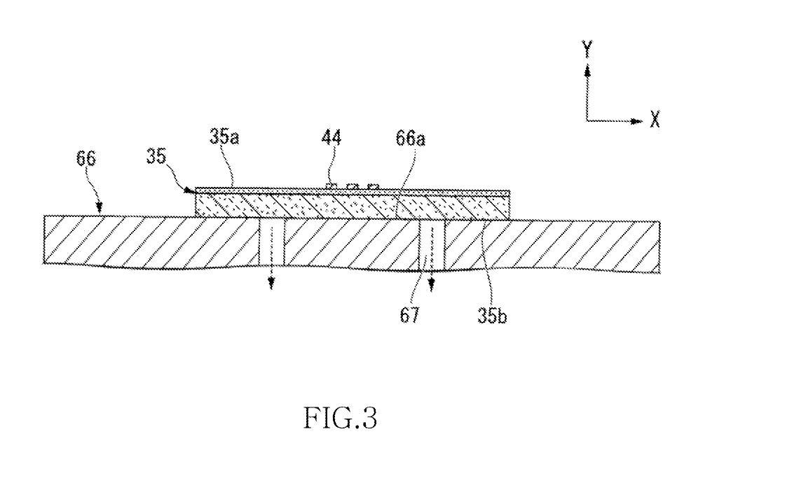

Next, in the step shown in FIG. 3, the first semiconductor chip 35 is placed on a stage 66 of a bonding system so that the top surface 66a of the stage 66 is in contact with the other surface 35b (flat surface) of the first semiconductor chip 35. The first semiconductor chip 35 is then sucked from suction holes 67 which are formed in the stage 66 and connected to a not-show vacuum system. Since the stage 66 sucks the flat other surface 35b of the first semiconductor chip 35, the first semiconductor chip 35 can be sucked in a favorable state.

In this phase of process, the one surface 35a of the first semiconductor chip 35 where the plurality of first bump electrodes 44 are formed is directed upward.

The stage 66 includes a heater (not shown). The heater heats the first semiconductor chip 35 to a predetermined temperature (for example, 100° C.).

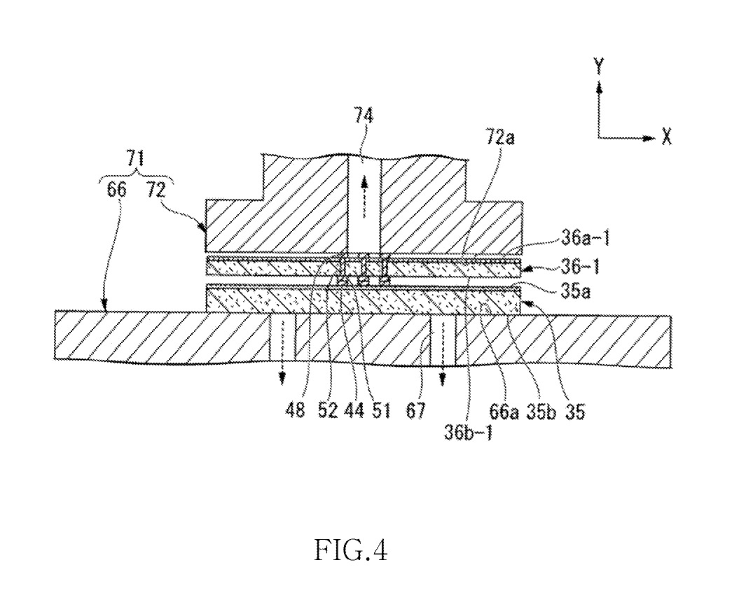

Next, in the step shown in FIG. 4, a suction surface 72a of a bonding tool 72 constituting a bonding system 71 is brought into contact with the one surface 36a-1 side of the second semiconductor chip 36-1 (specifically, the plurality of second bump electrodes 48).

The one surface 36a-1 side of the second semiconductor chip 36-1 is sucked to the suction surface 72a of the bonding tool 72 through a suction hole 74 which is connected to a not-shown vacuum system and exposed in the suction surface 72a. The bonding tool 72 includes a heater (not shown). The heater heats the second semiconductor chip 36-1 to a predetermined temperature (for example, 300° C.).

Next, the bonding tool 72 is moved so that the first bump electrodes 44 are opposed to the third bump electrodes 50. The second semiconductor chip 36 is thereby arranged on the first semiconductor chip 35.

The bonding tool 72 then presses the second semiconductor chip 36-1 against the first semiconductor chip 35 to electrically connect (join) the first bump electrodes 44 and the third bump electrodes 51. The second semiconductor chip 36-1 is thereby flip-chip mounted on the first semiconductor chip 35.

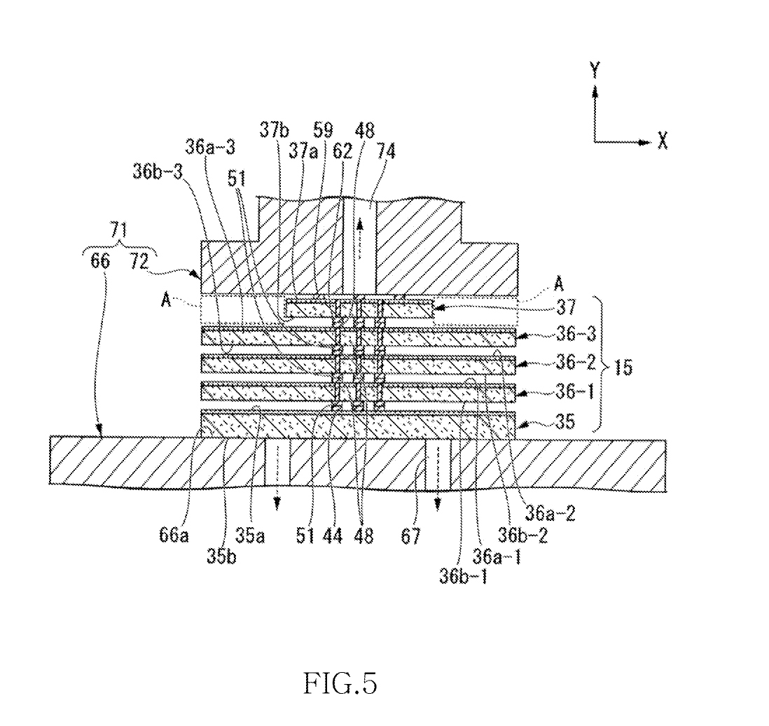

In the step shown in FIG. 5, the second semiconductor chip 36-2 is stacked on the second semiconductor chip 36-1 and the third bump electrodes 51 of the second semiconductor chip 36-2 are electrically connected (joined) to the second bump electrodes 48 of the second semiconductor chip 36-1 by the same technique as in the step shown in FIG. 4.

As a result, the second semiconductor chip 36-2 is flip-chip mounted on the second semiconductor chip 36-1.

The second semiconductor chip 36-3 is stacked on the second semiconductor chip 36-2 and the third bump electrodes 51 of the second semiconductor chip 36-3 are electrically connected (joined) to the second bump electrodes 48 of the second semiconductor chip 36-2 by the same technique as in the step shown in FIG. 4.

As a result, the second semiconductor chip 36-3 is flip-chip mounted on the second semiconductor chip 36-2.

The third semiconductor chip 37 is stacked on center of the second semiconductor chip 36-3 and the fifth bump electrodes 62 of the third semiconductor chip 37 are electrically connected (joined) to the second bump electrodes 48 of the second semiconductor chip 36-3 by the same technique as in the step shown in FIG. 4.

As a result, the third semiconductor chip 37 is flip-chip mounted on the second semiconductor chip 36-3 and the chip stacked body 15 is constructed with the first to third semiconductor chips 35, 36-1, 36-2, 36-3 and 37.

Since the third semiconductor chip 37 has an external size smaller than that of the second semiconductor chip 36-3 in the X direction, chip non-mounting areas A opposed to the one surface 36a-3 of the second semiconductor chip 36-3 (areas where the third semiconductor chip 37 is not mounted) are formed around the first semiconductor chip 37.

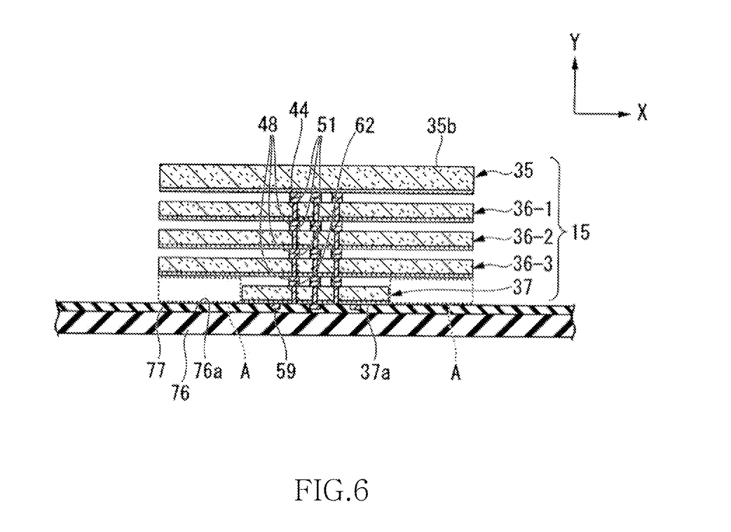

In the step shown in FIG. 6, the chip stacked body 15 is taken out of the bonding system 71 shown in FIG. 5. The chip stacked body 15 is then flipped over.

The chip stacked body 15 is pasted onto a tape base 76 via an adhesive layer 77 arranged on one surface 76a of the tape base 76 so that the adhesive layer 77 is in contact with the one surface 37a of the third semiconductor chip 37. The plurality of fourth bump electrodes 59 formed on the one surface 37a of the third semiconductor chip 37 are thereby buried in the adhesive layer 77.

Note that FIG. 6 shows only one chip stacked body 15 because it is difficult to illustrate a plurality of chip stacked bodies 15. In fact, a plurality of chip stacked bodies 15 are pasted to the tape base 76 via the adhesive layer 77.

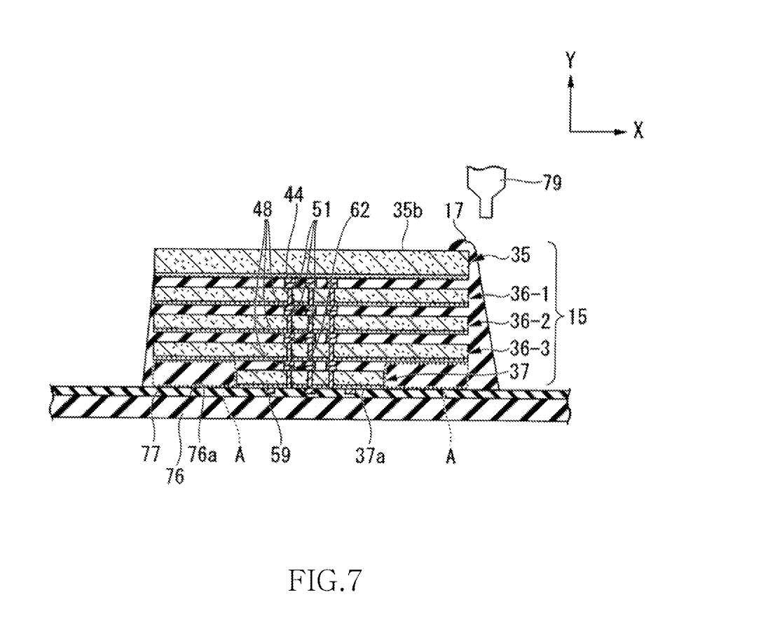

In the step shown in FIG. 7, a dispenser 79 supplies a semi-cured underfill material 17 (the base material of the first sealing resin 16 shown in FIG. 1) to a sidewall of the chip stacked body 15. The gaps between the first to third semiconductor chips 35, 36-1, 36-2, 36-3, and 37 are filled with the underfill material 17 by a capillary action.

As described above, the chip stacked body 15 is pasted so that the one surface 37a of the third semiconductor chip 37 having an external size smaller than that of the first and second semiconductor chips 35, 36-1, 36-2, and 36-3 in the X direction is in contact with the adhesive layer 77. The second semiconductor chip 36-3 and the adhesive layer 77 can thus create therebetween a gap where the semi-cured underfill material 17 can flow by a capillary action.

Consequently, when the dispenser 79 supplies the semi-cured underfill material 17 to the sidewall of the chip stacked body 15, the gap between the second semiconductor chip 36-3 and the third semiconductor chip 37 (in other words, a gap formed by the stacking of semiconductor chips having different external sizes) can be filled with the underfill material 17 by a capillary action through the gap between the semiconductor chip 36-3 and the adhesive layer 77.

This can reduce the number of filling operations of the underfill material 17, which conventionally needs to be two, to one. The steps for manufacturing the semiconductor device 10 can thus be simplified.

The single filling operation of the underfill material 17 can also reduce the heat load on the chip stacked body 15 in the underfill material filling step.

The plurality of bump electrodes 59 are buried in the adhesive layer 77 when the underfill material 17 is supplied. The underfill material 17 is thus prevented from adhering to the fourth bump electrodes 59 which function as the external connection terminals of the chip stacked body 15.

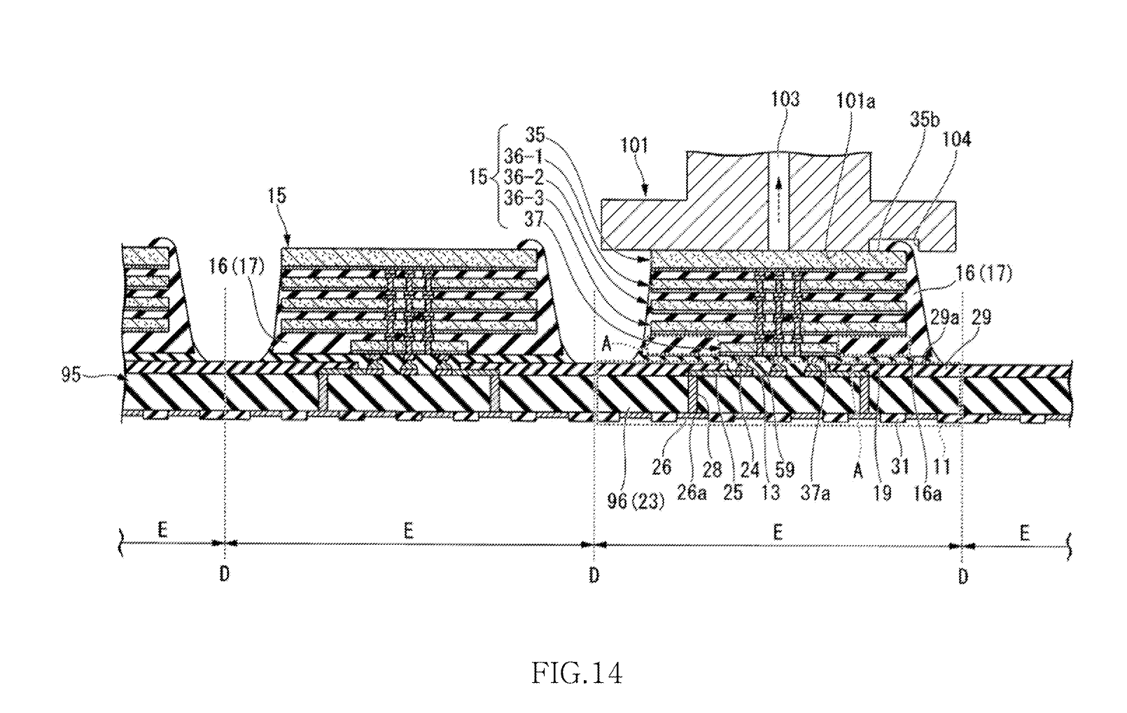

This can improve the electrical connection reliability between the wiring substrate 11 and the chip stacked body 15 when the chip stacked body 15 having the first sealing resin (fully-cured underfill material 17) is mounted on the wiring substrate 11 in the step shown in FIG. 14 to be described later.

The semi-cured underfill material 17 is supplied after the chip stacked body 15 is pasted so that the one surface 37a of the third semiconductor chip 37 is in contact with the adhesive layer 77. The underfill material 17 is thus prevented from adhering to the one surface 37a of the third semiconductor chip 37. Since the underfill material 17 will not be trapped into between the fourth bump electrodes 59 and the wire bumps 13, the wiring substrate 11 and the chip stacked body 15 can be connected in a favorable manner.

As shown in FIG. 7, the underfill material 17 may run over the other surface 35b of the first semiconductor chip 35 arranged at the uppermost layer. Such a phenomenon does not matter since there is no bump electrode formed on the other surface 35b of the first semiconductor chip 35.

In the step shown in FIG. 7, the semi-cured underfill material 17 flows through the gap between the adhesive layer 77 and the second semiconductor chip 36-3 while the gap between the second semiconductor chip 36-3 and the third semiconductor chip 37 is being filled with the underfill material 17. When the gap between the second semiconductor chip 36-3 and the third semiconductor chip 37 is filled with the underfill material 17, the gap between the adhesive layer 77 and the second semiconductor chip 36-3 is also filled with the underfill material 17. The underfill material 17 is thus also formed in the chip non-mounting areas A.

In such a manner, the underfill material 17 serving as the base material of the first sealing resin 16 is formed in the chip non-mounting areas A around the third semiconductor chip 37. In the step shown in FIG. 14 to be described later, where the chip stacked body 15 having the first sealing resin 16 is mounted on the wiring substrate 11, the adhesive member 19 can thus be formed not only in the gap between the third semiconductor chip 37 and the wiring substrate 11 but also in the gap between the bottom surface 16a of the first sealing resin 16 and the wiring substrate 11.

This increases the adhesion area between the chip stacked body 15 having the first sealing resin 16 and the adhesive member 19 on the side of the one surface 37a of the third semiconductor chip 37. The increased adhesion area can reduce the stress to be applied to the fourth bump electrodes 49 when an external force is applied to the chip stacked body 15 after the mounting of the chip stacked body 15 on the wiring substrate 11. The electric connection reliability between the chip stacked body 15 and the wiring substrate 11 can thus be improved.

The adhesive layer 77 preferably has low wettability to the underfill material 17. For example, an ultraviolet curing adhesive layer may be used as the adhesive layer 77.

The adhesive layer 77 having low wettability to the underfill material 17 can be used to suppress spreading of the underfill material 17 over the adhesive layer 77. As a result, the underfill material 17 can be efficiently filled into the gaps between the first to third semiconductor chips 35, 36-1, 36-2, 36-3, and 37.

Note that in the step shown in FIG. 7, the entire chip stacked body 15 pasted on the tape base 76 via the adhesive layer 77 is filled with the underfill material 17.

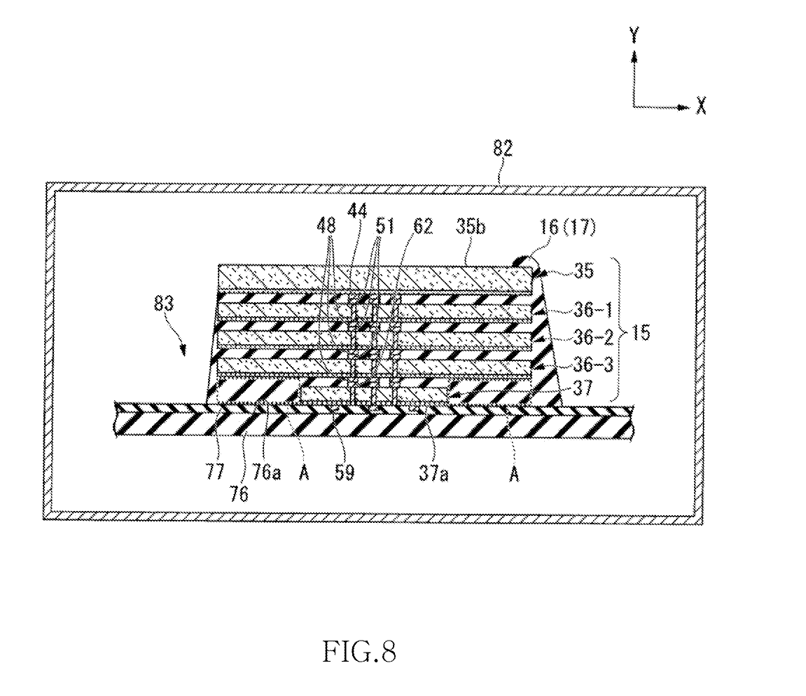

Next, in the step shown in FIG. 8, the structure shown in FIG. 7 (specifically, the structure including the tape base 76, the adhesive layer 77, the chip stacked body 15, and the semi-cured underfill material 17) is heated in a baking furnace 82 to fully cure the underfill material 17. Consequently, the first sealing resin 16 made of the fully-cured underfill material 17, having a generally trapezoidal shape in a side view, is formed on the chip stacked body 15.

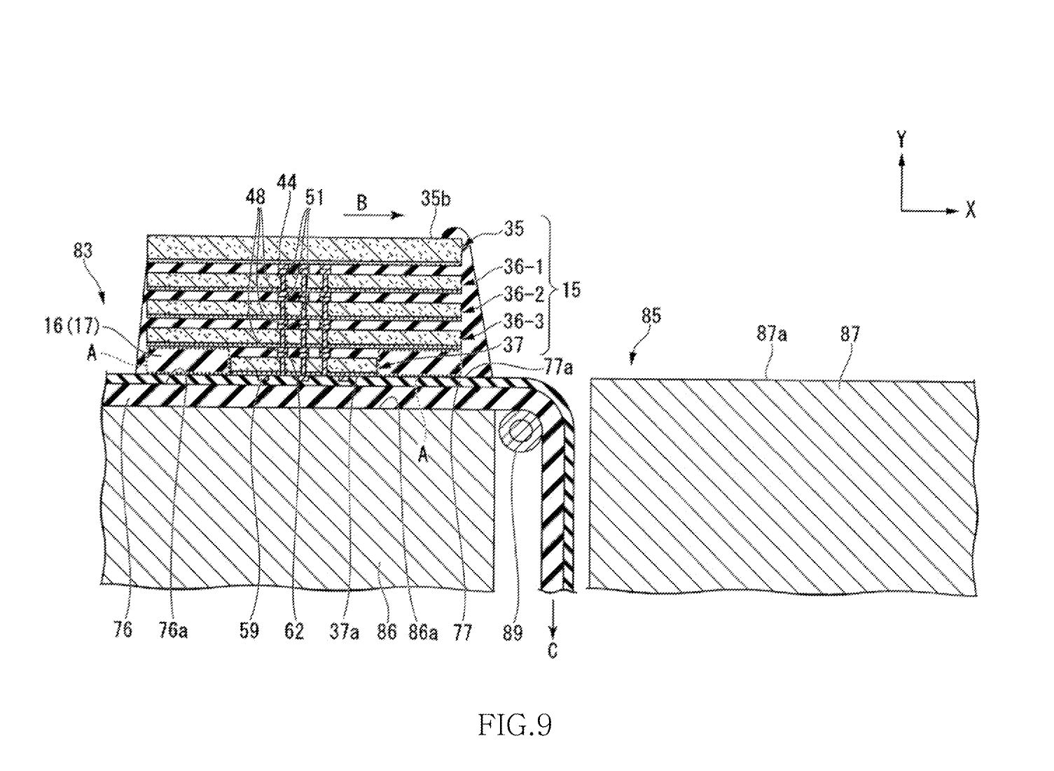

In the step shown in FIG. 9, the structure 83 stored in the baking furnace 82 shown in FIG. 8 (specifically, the structure including the tape base 76, the adhesive layer 77, the chip stacked body 15, and the first sealing resin 16) is taken out. The adhesive layer 77 is then irradiated with ultraviolet rays to reduce the adhesive power of the adhesive layer 77.

Referring to FIG. 9, the configuration of a chip stacked body stripping system 85 on which the structure 83 including the adhesive layer 77 of reduced adhesive power is placed will be described.

The chip stacked body stripping system 85 includes a first stage 86, a second stage 87, not-shown tape base collection unit, a roller 89, and not-shown tape base feeding means.

The first stage 86 has a flat-shaped base placement surface 86a (top surface) where the tape base 76 with the pasted chip stacked body 15 is placed on.

The second stage 87 has a chip stacked body collection surface 87a (top surface) for collecting the chip stacked body 15 stripped from the adhesive layer 77. The chip stacked body collection surface 87a is formed as a flat surface, and arranged to be flush with the top surface 77a of the adhesive layer 77 that constitutes the structure 83 placed on the base placement surface 86a.

The tape base collection unit is arranged between the first stage 86 and the second stage 87. The tape base collection unit collects the adhesive layer 77 and the tape base 76 that move in the C direction (vertical direction) after the removal of the chip stacked body 15.

The roller 89 is a member for changing the moving direction of the tape base 76 moving on the first stage 86 in the B direction (horizontal direction) to the C direction.

The tape base feeding means (not shown) are intended to move the tape base 76 in the B direction and the C direction.

The structure 83 including the adhesive layer 77 of reduced adhesive power is placed on the chip stacked body stripping system 85.

Specifically, a portion of the tape base 76 where the chip stacked body 15 is pasted is placed on the base placement surface 86a. A portion of the tape base 76 where no chip stacked body 15 is pasted is turned to the C direction via the roller 89, and the end of the tape base 76 lying in the tape base collection unit is connected to the tape base feeding means (not shown). This completes the installation of the structure 83 on the chip stacked body stripping system 85. At this phase of process, the tape base 76 remains at rest, not being moved in the B direction or C direction.

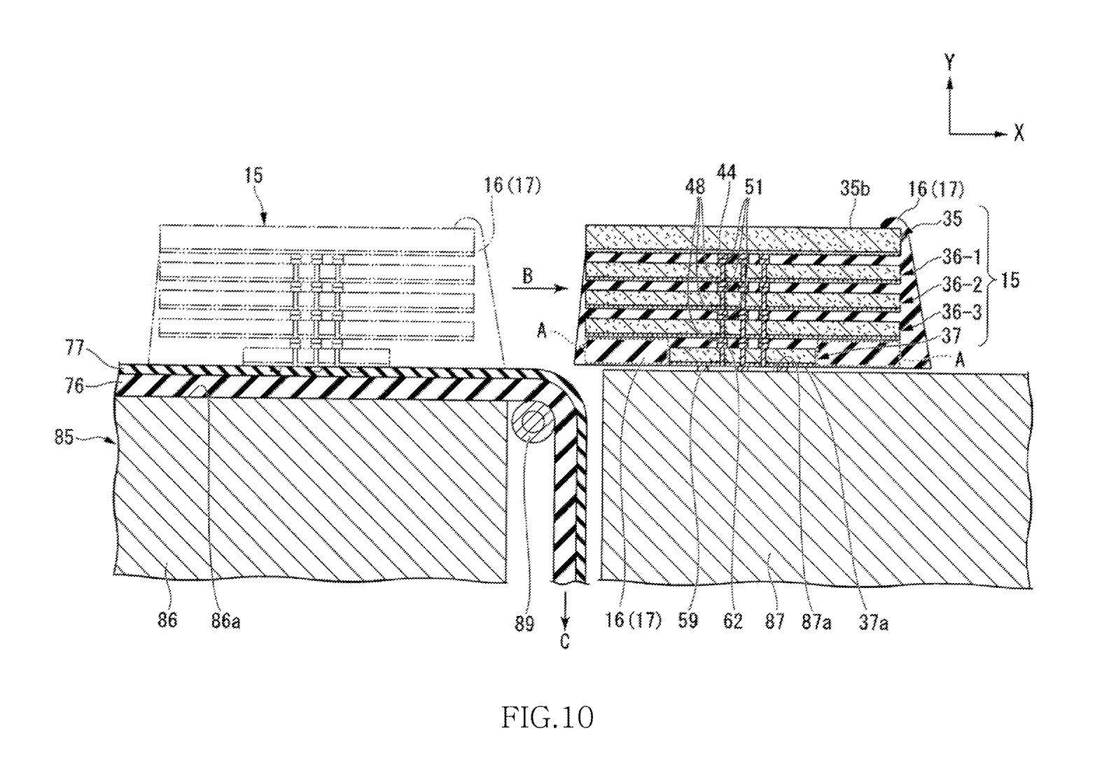

In the step shown in FIG. 10, the adhesive layer 77 and the tape base 76 are removed from the chip stacked body 15.

Specifically, the tape base 76 is moved in the B direction from the state shown in FIG. 9, so that the tape base 76 is moved together with the chip stacked body 15 on the base placement surface 86a. When the chip stacked body 15 passes over the roller 89, the tape base 76 and the adhesive layer 77 are collected in the C direction. The chip stacked body 15 moving in the B direction is stripped from the adhesive layer 77 of reduced adhesive power in the horizontal direction (B direction). The stripped chip stacked body 15 moves to the chip stacked body collection surface 87a of the second stage 87.

In other words, in the step shown in FIG. 10, the chip stacked body 15, which includes the through electrodes 52 and 63 and is thus vulnerable to an external force in the Y direction (the stacking direction of the first to third semiconductor chips 35, 36-1, 36-2, 36-3, and 37), is horizontally moved so that the chip stacked body 15 having the first sealing resin 16 is stripped from the adhesive layer 77.

As described above, the adhesive power of the adhesive layer 77 is reduced before the tape base 76 and the chip stacked body 15 are moved in the horizontal direction (B direction). The tape base 76 and the adhesive layer 77 are moved in the vertical direction (C direction) on the way to strip the chip stacked body 15 having the first sealing resin 16 from the adhesive layer 77. This can prevent breakage of the chip stacked body 15 since an external force in the Y direction is less likely to be applied to the chip stacked body 15.

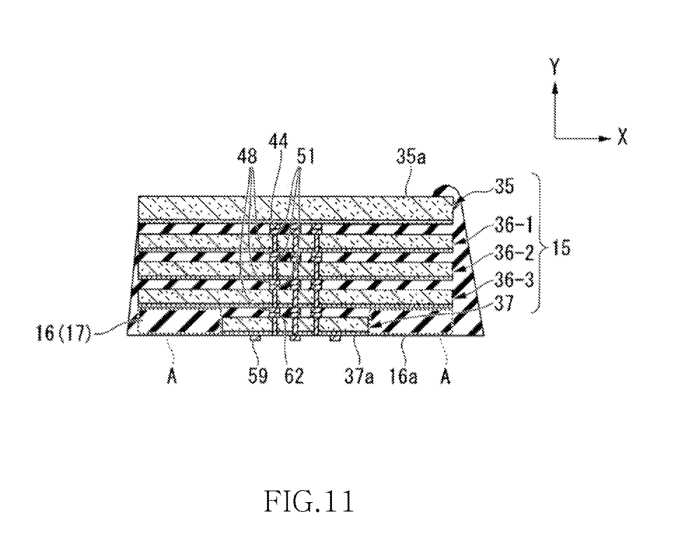

In the step shown in FIG. 11, the chip stacked body 15 having the first sealing resin 16, moved to the chip stacked body collection surface 87a of the second stage 87 shown in FIG. 10, is collected.

Note that FIG. 11 shows only one chip stacked body 15 having a first sealing resin 16 because it is difficult to illustrate a plurality of chip stacked bodies 15 having a first sealing resin 16. In fact, a plurality of chip stacked bodies 15 having a first sealing resin 16 are collected in the step shown in FIG. 11.

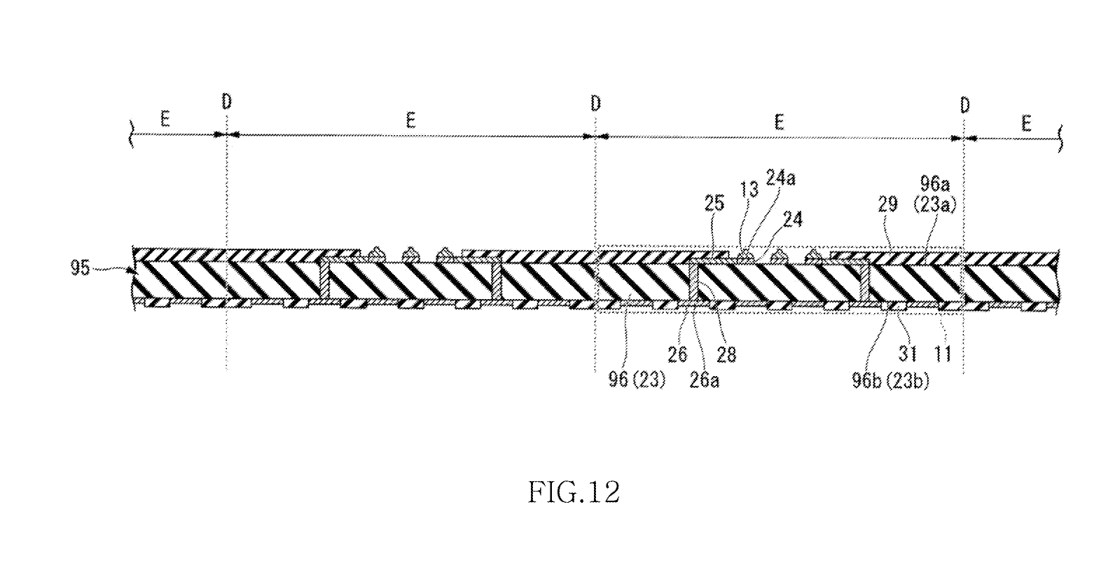

In the step shown in FIG. 12, a wiring mother substrate 95 including a plurality of connected wiring substrates 11 is formed by a known technique.

The configuration of the wiring mother substrate 95 will be described with reference to FIG. 12.

The wiring mother substrate 95 includes an insulating base 96 which includes a plurality of wiring substrate forming areas E and dicing lines D for sectioning the wiring substrate forming areas E. The wiring substrate 11 described in FIG. 1 is formed in each of the plurality of wiring substrate forming areas E.

The insulating base 96 is cut into a plurality of substrate bodies 23 (one of the components of each wiring substrate 11) along the dicing lines D. One surface 96a of the insulating base 96 therefore coincides with the one surfaces 23a of the substrate bodies 23. The other surface 96b of the insulating base 96 coincides with the other surfaces 23b of the substrate bodies 23.

After the formation of the wiring base substrate 95, wire bumps 13 are formed by using a wire bonding system (not shown) on the bump forming surfaces 24a of the plurality of connection pads 24 formed on the wiring mother substrate 95.

For example, a wire bump 13 (protruded bump) is formed by melting the extremity of a gold (Au) or copper (Cu) wire to form a ball on the extremity, bonding the wire having the ball to the bump forming surface 24a of a connection pad 24 by thermo-sonic bonding, and then pulling off the rear end of the wire.

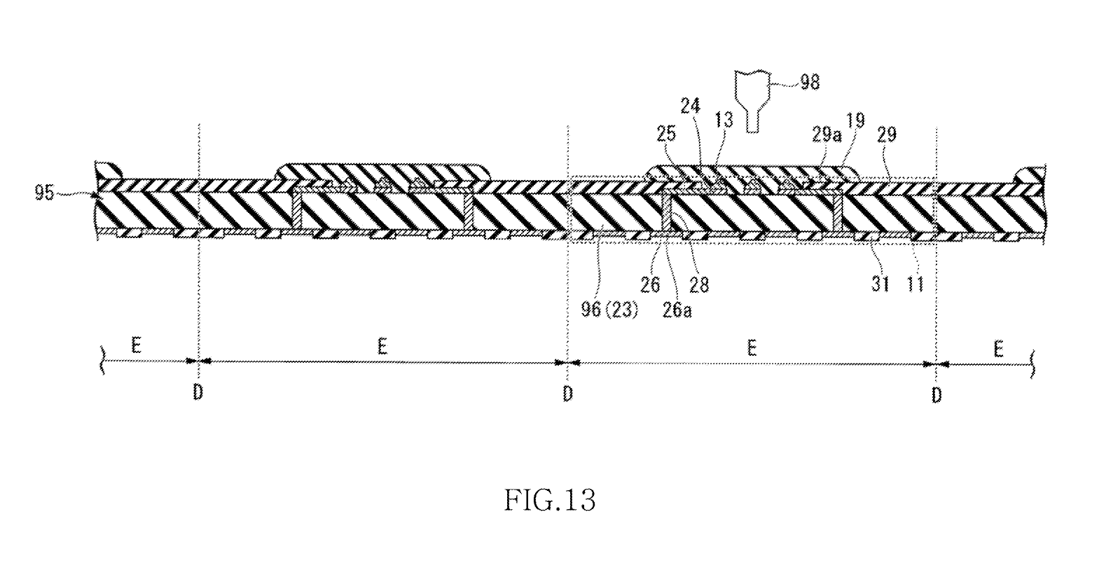

In the step shown in FIG. 13, adhesive members 19 are formed to cover the plurality of connection pads 24 and the wire bumps 13 formed in the wiring substrate forming areas E. For example, the adhesive members 19 are formed by supplying a non-conductive paste (NCP), the base material of the adhesive members 19, from a dispenser 98. The adhesive members 19 are formed on all the wiring substrate forming areas E.

In the step shown in FIG. 14, the other surface 35b of the first semiconductor chip 35 constituting the chip stacked body 15 shown in FIG. 11 is sucked to a suction surface 101a of a bonding tool 101. A heater (not shown) included in the bonding tool 101 heats the chip stacked body 15 to a predetermined temperature (for example, 300° C.).

The bonding tool 101 is then moved so that the wire bumps 13 are opposed to the fourth bump electrodes 59. The chip stacked body 15 having the first sealing resin 16 is then pressed against the wiring substrate 11 via the adhesive member 19, whereby the wire bumps 13 are electrically connected (joined) to the fourth bump electrodes 59.

Consequently, the chip stacked body 15 having the first sealing resin 16 is flip-chip mounted on the wiring substrate 11.

Since the chip stacked body 15 having the first sealing resin 16 is pressed against the wiring substrate 11 via the adhesive member 19, the adhesive member 19 spreads out laterally to fill the gaps between the one surface 37a of the third semiconductor chip 37 and the wiring substrate 11 and between the bottom surface 16a of the first sealing resin 16 and the wiring substrate 11.

The configuration of the bonding tool 101 used in the step shown in FIG. 14 will be described. Referring to FIG. 14, the bonding tool 101 includes the suction surface 101a, a suction hole 103, and a groove portion 104. The suction surface 101a is a flat surface. The suction surface 101a makes contact with the other surface 35b of the first semiconductor chip 35 when the chip stacked body 15 is sucked to the bonding tool 101.

The suction hole 103 is exposed in the suction surface 101a. The suction hole 103 is connected to a not-shown vacuum system.

The groove portion 104 is a groove-shaped recess for preventing contact between the first sealing resin 16 running over the other surface 35b of the first semiconductor chip 35 and the bonding tool 101.

Since the bonding tool 101 for sucking the chip stacked body 15 having the first sealing resin 16 is provided with the groove portion 104 for preventing contact between the first sealing resin 16 running over the other surface 35b of the first semiconductor chip 35 and the bonding tool 101, the chip stacked body 15 is prevented from being obliquely sucked to the suction surface 101a of the bonding tool 101.

As a result, the chip stacked body 15 is prevented from being obliquely pressed against the wiring substrate 11 for mounting. The fourth bump electrodes 59 can thus be joined to the wire bumps 103 in a favorable manner.

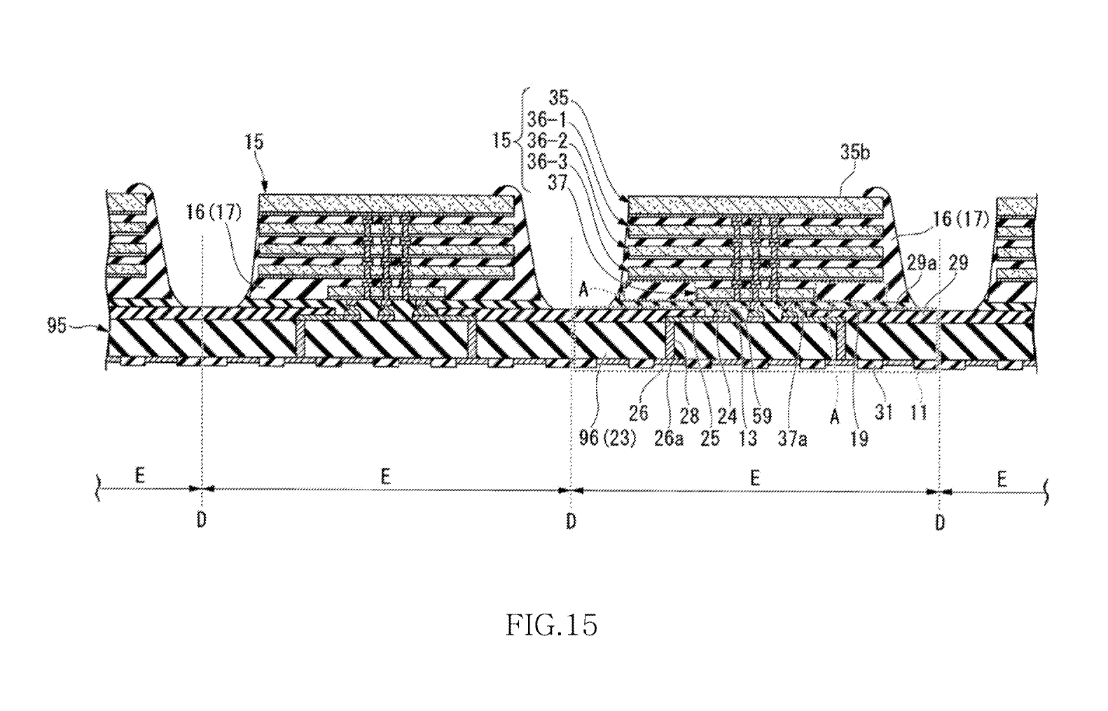

In the step shown in FIG. 15, chip stacked bodies 15 having a first sealing resin 16 are flip-chip mounted on all the wiring substrates 11 by the same technique as in the step shown in FIG. 14.

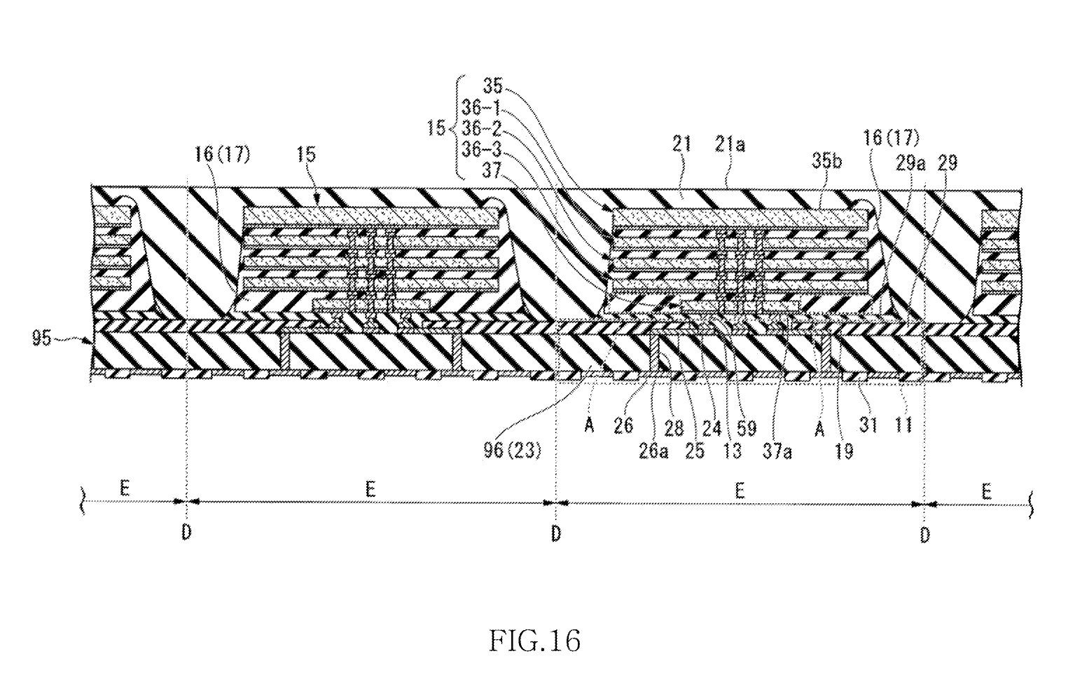

In the step shown in FIG. 16, the plurality of chip stacked bodies 15 and the first sealing resins 16 mounted on the wiring mother substrate 95 are simultaneously sealed with the second sealing resin 21. The second sealing resin 21 is formed to have a flat top surface 21a. For example, a molded resin may be used as the second sealing resin 21.

Such a second sealing resin 21 is formed by the following method. Initially, the structure shown in FIG. 15 is put in a cavity formed inside a mold (not shown) which is composed of an upper mold and a lower mold. A molten thermosetting resin (the base material of the second sealing resin 21) such as epoxy resin is injected into the cavity through gates (not shown) formed in the mold.

As a result, the plurality of chip stacked bodies 15 and the first sealing resins 16 mounted on the wiring mother substrate 95 are covered by the thermosetting resin. The thermosetting resin is then cured at a predetermined temperature (for example, 180° C.), whereby the second sealing resin 21 made of the fully-cured thermosetting resin is formed.

Since the gaps between the first to third semiconductor chips 35, 36-1, 36-2, 36-3, and 37 constituting the chip stacked bodies 15 are filled with the first sealing resins 16 in advance, the occurrence of a void between the first to third semiconductor chips 35, 36-1, 36-2, and 37 can be prevented in the step of forming the second sealing resin 21.

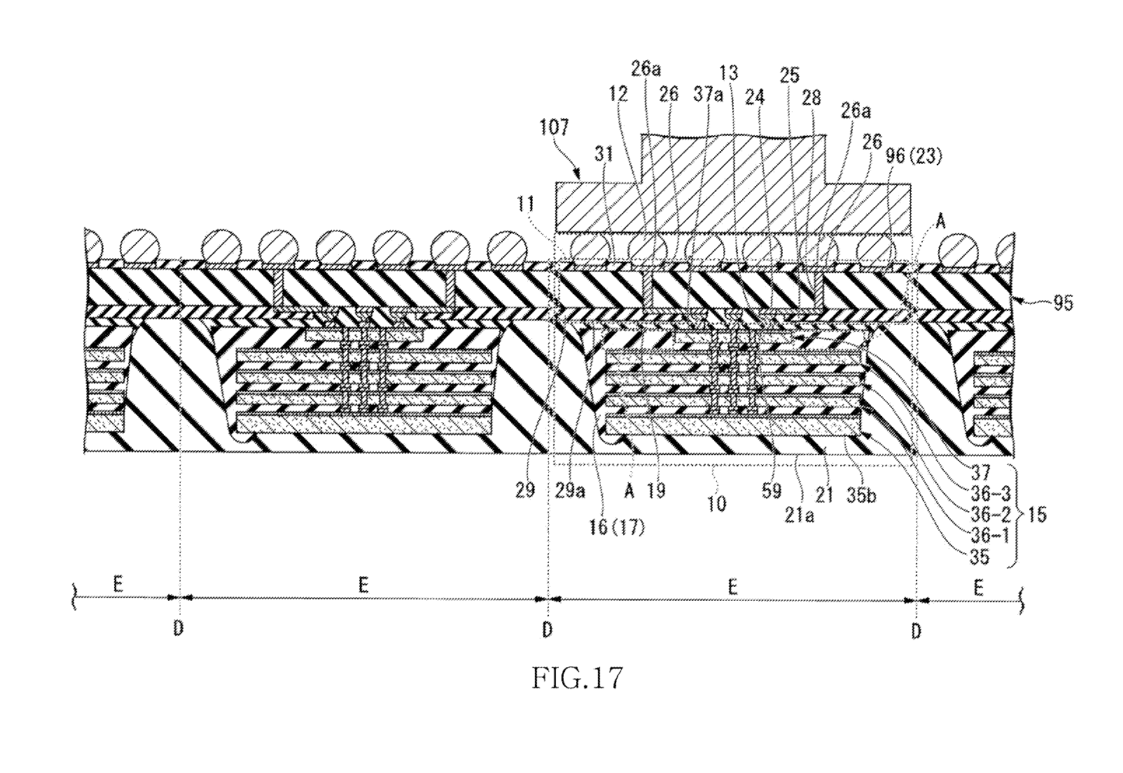

In the step shown in FIG. 17, external connection terminals 12 are mounted on the terminal mounting surfaces 26a of the lands 26 formed on the wiring substrates 11. For example, solder balls may be used as the external connection terminals 12.

The structure shown in FIG. 16 is flipped over before the solder balls (external connection terminals 12) are mounted on the terminal mounting surfaces 26a of the lands 26 by using a mount tool 107. The mount tool 107 has suction holes (not shown) capable of sucking and holding a plurality of solder balls (external connection terminals 12).

The external connection terminals 12 are mounted on the terminal mounting surfaces 26a of the lands 26 formed on all the wiring substrates 11. As a result, a structure including semiconductor devices 10 formed in the plurality of wiring substrate forming areas E is manufactured. In this phase of process, the plurality of semiconductor devices 10 are in a connected form, not separated in pieces.

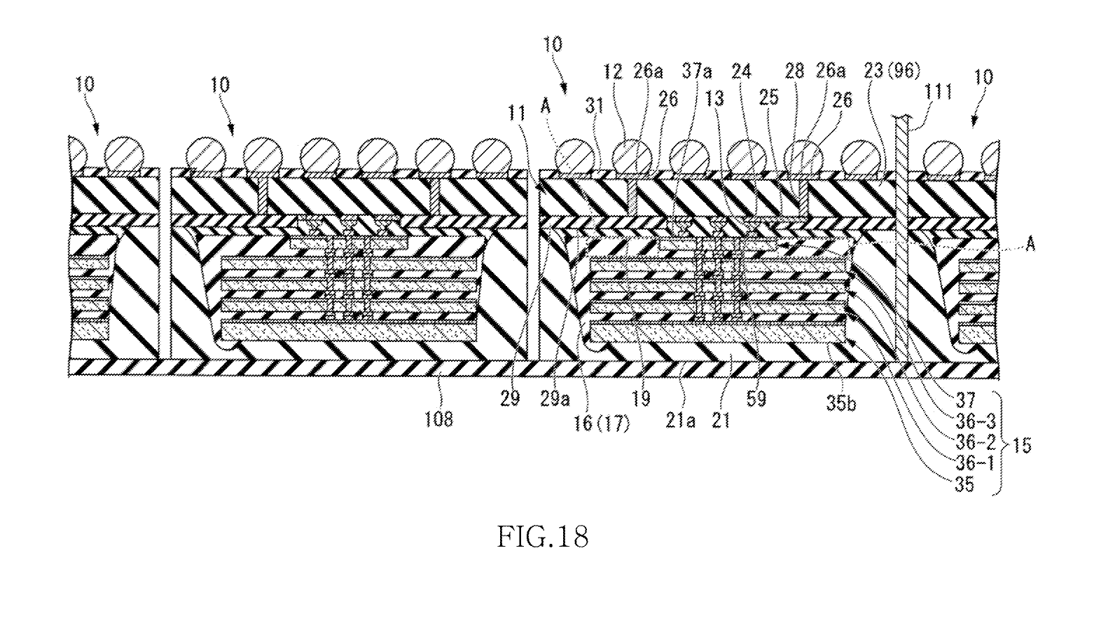

In the step shown in FIG. 18, a dicing tape 108 is pasted to the top surface 21a of the second sealing resin 21 constituting the structure shown in FIG. 17 (specifically, the structure including the plurality of connected semiconductor devices 10). The structure shown in FIG. 17 is then cut into a plurality of pieces of semiconductor devices 10 along the dicing lines D by a dicing blade 111.

Subsequently, the plurality of pieces of semiconductor devices 10 are picked up from the dicing tape 108 shown in FIG. 18, whereby a plurality of semiconductor devices 10 according to the first embodiment shown in FIG. 1 are manufactured.

According to the manufacturing method of the first embodiment, the chip stacked body 15 is pasted so that the one surface 37a of the third semiconductor chip 37 having an external size smaller than that of the first and second semiconductor chips 35, 36-1, 36-2, and 36-3 in the X direction is in contact with the adhesive layer 77. The second semiconductor chip 36-3 and the adhesive layer 77 can thus create therebetween a gap where the semi-cured underfill material 17 can flow by a capillary action.

Consequently, when the dispenser 79 supplies the semi-cured underfill material 17 to the sidewall of the chip stacked body 15, the gap between the second semiconductor chip 36-3 and the third semiconductor chip 37 (in other words, a gap formed by the stacking of semiconductor chips having different external sizes) can be filled with the underfill material 17 by a capillary action through the gap between the semiconductor chip 36-3 and the adhesive layer 77.

This can reduce the number of filling operations of the underfill material 17, which conventionally needs to be two, to one. The steps for manufacturing the semiconductor device 10 can thus be simplified.

The single filling operation of the underfill material 17 can also reduce the heat load on the chip stacked body 15 in the underfill material filling step.

The plurality of bump electrodes 59 are buried in the adhesive layer 77 when the underfill material 17 is supplied. The underfill material 17 is thus prevented from adhering to the fourth bump electrodes 59 which function as the external connection terminals of the chip stacked body 15.

This can improve the electrical connection reliability between the wiring substrate 11 and the chip stacked body 15 when the chip stacked body 15 having the first sealing resin 16 (fully-cured underfill material 17) is mounted on the wiring substrate 11.

The semi-cured underfill material 17 is supplied after the chip stacked body 15 is pasted so that the one surface 37a of the third semiconductor chip 37 is in contact with the adhesive layer 77. The underfill material 17 is thus prevented from adhering to the one surface 37a of the third semiconductor chip 37. Since the underfill material 17 will not be trapped into between the fourth bump electrodes 59 and the wire bumps 13, the wiring substrate 11 and the chip stacked body 15 can be connected in a favorable manner.

The underfill material 17 may run over the other surface 35b of the first semiconductor chip 35 arranged at the uppermost layer. Such a phenomenon does not matter since there is no bump electrode formed on the other surface 35b of the first semiconductor chip 35.

### Second Embodiment

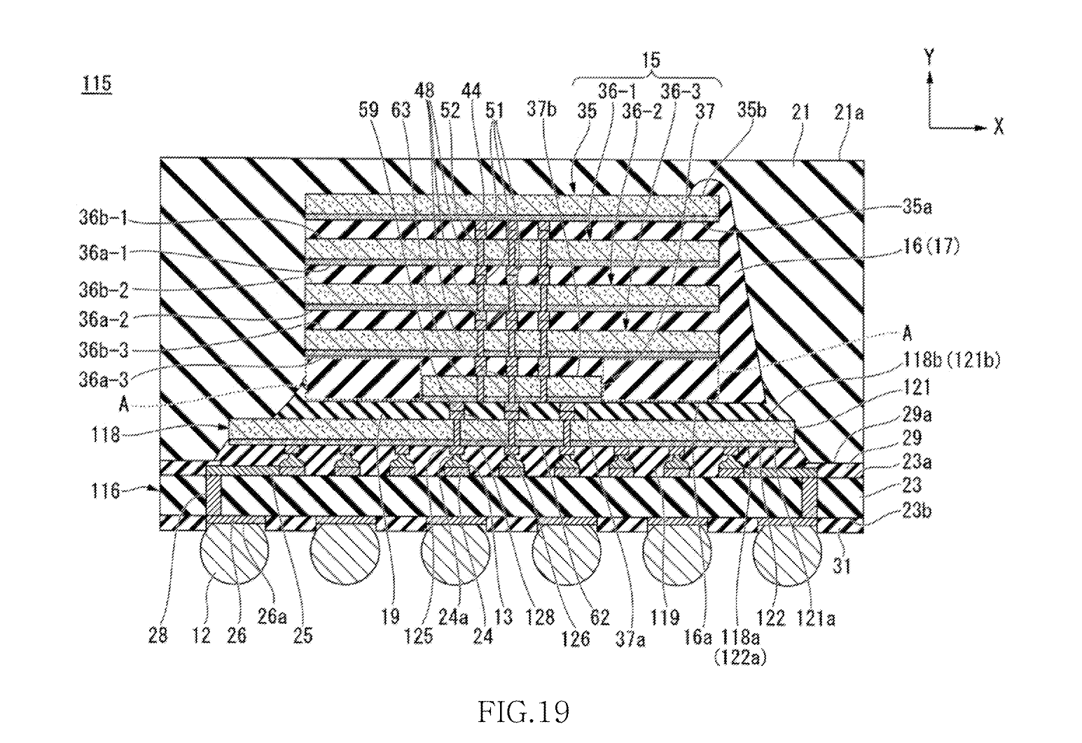

FIG. 19 is a sectional view showing a general configuration of a semiconductor device according to a second embodiment of the present invention. In FIG. 19, the same components as those of the semiconductor device 10 according to the first embodiment are designated by the same reference symbols.

Referring to FIG. 19, a semiconductor device 115 according to the second embodiment has the same configuration as that of the semiconductor device 10 according to the first embodiment except that a wiring substrate 116 is provided instead of the wiring substrate 11 of the semiconductor device 10, and that a fourth semiconductor chip 118 and a third sealing resin 119 are further provided.

The wiring substrate 116 has the same configuration as that of the wiring substrate 11 described in the first embodiment except that the connection pads 24 are arranged in different positions from those on the wiring substrate 11.

The connection pads 24 are arranged on the one surface 23a of the substrate body 23 so as to be opposed to seventh bump electrodes 126 formed on the fourth semiconductor chip 118.

The fourth semiconductor chip 118 is arranged between the wiring substrate 116 and the chip stacked body 15. The fourth semiconductor chip 118 is a thinned semiconductor chip (for example, 50 μm or less in thickness) of rectangular shape. The fourth semiconductor chip 118 has a size (external size) greater than that of the first and second chips 35, 36-1, 36-2, and 36-3 in the X direction.

The fourth semiconductor chip 118 has a function different from those of the first to third semiconductor chips 35, 36-1, 36-2, 36-3, and 37. If the first and second semiconductor chips 35, 36-1, 36-2, and 36-3 are semiconductor memory devices and the third semiconductor chip 37 is a control chip having an interface function, the fourth semiconductor chip 118 may be a logic semiconductor chip, for example.

The following description of the second embodiment deals with an example where a logic semiconductor chip is used as the fourth semiconductor chip 118.

The fourth semiconductor chip 118 includes a semiconductor substrate 121, a circuit element layer 122, sixth bump electrodes 125, the seventh bump electrodes 126, and through electrodes 128.

The semiconductor substrate 121 has the same configuration as that of the semiconductor substrate 46 described in the first embodiment except having an external size greater than that of the semiconductor substrate 46 in the X direction.

The circuit element layer 122 is formed on the surface 121a of the semiconductor substrate 121. The circuit element layer 122 has a multilayer wiring structure and includes a large number of logic circuits (not shown).

A plurality of sixth bump electrodes 125 are formed on one surface 118a of the fourth semiconductor chip 118 (the surface 122a of the circuit electrode layer 122). The plurality of sixth bump electrodes 125 are arranged to be opposed to the connection pads 24 formed on the wiring substrate 11.

Among the plurality of sixth bump electrodes 125, ones lying in the center of the one surface 118a of the fourth semiconductor chip 118 are arranged to be opposed to the seventh bump electrodes 126.

The sixth bump electrodes 125 are joined (electrically connected) to the wire bumps 13. The sixth bump electrodes 125 are electrically connected to the connection pads 24 of the wiring substrate 11 through the wire bumps 13.

In other words, the fourth semiconductor chip 118 is flip-chip mounted on the connection pads 24 of the wiring substrate 11.

The seventh bump electrodes 126 are formed in the center area of the other surface 118b of the fourth semiconductor chip (the backside 121b of the semiconductor substrate 121). The seventh bump electrodes 126 are arranged to be opposed to the fourth bump electrodes 59 formed on the third semiconductor chip 37 constituting the chip stacked body 15.

The through electrodes 128 are formed to run through the semiconductor substrate 121 and the circuit element layer 122 at positions between the sixth bump electrodes 125 and the seventh bump electrodes 126. The through electrodes 128 are connected at one ends to the sixth bump electrodes 125 and at the other ends to the seventh bump electrodes 126. The through electrodes 128 thereby electrically connect the sixth bump electrodes 125 and the seventh bump electrodes 126.

The third sealing resin 119 is formed to fill the gap between the wiring substrate 11 and the fourth semiconductor chip 118. The third sealing resin 119 thereby seals the junctions between the wiring substrate 11 and the fourth semiconductor chip 118.

The chip stacked body 15 having the first sealing resin 16 is arranged on the fourth semiconductor chip 118. The fourth bump electrodes 59 constituting the chip stacked body 15 are joined (electrically connected) to the seventh bump electrodes 126 of the fourth semiconductor chip 118. Consequently, the chip stacked body 15 is flip-flop mounted on the fourth semiconductor chip 118 and electrically connected to the wiring substrate 11 through the fourth semiconductor chip 118.

The adhesive member 19 is arranged to fill the gaps between the one surface 37a of the third semiconductor chip 37 and the fourth semiconductor chip 118 and between the bottom surface 16a of the first sealing resin 16 and the fourth semiconductor chip 118.

The second sealing resin 21 is formed on the top surface 29a of the first solder resist 29 so as to seal the chip stacked body 15, the first sealing resin 16, the adhesive member 19, the fourth semiconductor chip 118, and the third sealing resin 119.

As described above, the semiconductor device 115 according to the second embodiment includes the fourth semiconductor chip 118 between the wiring substrate 11 and the chip stacked body 15 having the first sealing resin 16. The fourth semiconductor chip 118 is electrically connected to the wiring substrate 11 and the chip stacked body 15. Such a semiconductor device 115 can provide the same effects as those of semiconductor device 10 of the first embodiment.

Specifically, the first sealing resin 16 is formed in the chip non-mounting areas A around the third semiconductor chip 37. The adhesive member 19 is formed to fill the gaps between the third semiconductor chip 37 and the fourth semiconductor chip 118 and between the bottom surface 16a of the first sealing resin 16 and the fourth semiconductor chip 118. Such a configuration increases the adhesion area between the chip stacked body 15 having the first sealing resin 16 and the adhesive member 19 on the side of the one surface 37a of the third semiconductor chip 37.

The increased adhesion area can reduce stress to be applied to the fourth bump electrodes 59 when an external force is applied to the chip stacked body 15. The electrical connection reliability between the chip stacked body 15 and the fourth semiconductor chip 118 can thus be improved.

A method for manufacturing the semiconductor device 115 according to the second embodiment will be described mainly with reference to FIG. 19.

Initially, the processing of the steps shown in FIGS. 2 to 11 described in the first embodiment is performed to form the chip stacked body 15 having the first sealing resin 16 shown in FIG. 11.

Next, a wiring mother substrate including a plurality of connected wiring substrates 116 shown in FIG. 19 is prepared by the same technique as in the step shown in FIG. 12 described in the first embodiment. Wire bumps 13 are then formed on the bump forming surfaces 24a of all the connection pads 24 formed on the wiring mother substrate.

Next, a semi-cured underfill material (the base material of the third sealing resin 119) is formed to cover the plurality of bumps 13 and the connection pads 24 formed on the wiring substrates 116 by the same technique as in the step shown in FIG. 13 described in the first embodiment.

The sixth bump electrodes 125 are electrically connected (joined) to the wire bumps 13 via the underfill material. As a result, fourth semiconductor chips 118 are flip-chip connected to the wiring substrates 116, and the third sealing resin 119 made of a fully-cured underfill material is formed to fill the gaps between the wiring substrates 116 and the fourth semiconductor chips 118.

Next, the same processing as that of the step shown in FIG. 13 described in the first embodiment is performed to form an adhesive layer 19 on the other surfaces 118b of the fourth semiconductor chips 118 so as to cover the plurality of seventh bump electrodes 126.

The same processing as that of the steps shown in FIGS. 14 and 15 described in the first embodiment is performed to electrically connect (join) the fourth bump electrodes 59 of the chip stacked bodies 15 having the first sealing resin 16 to the seventh bump electrodes 128 of the fourth semiconductor chips 118.

As a result, the chip stacked bodies 15 having the first sealing resin 16 are flip-chip mounted on the fourth semiconductor chips 118.

Next, the same processing as that of the steps shown in FIGS. 16 to 18 described in the first embodiment is performed to form a plurality of separate pieces of semiconductor devices 115 on the dicing tape 108 (see FIG. 18).

The plurality of pieces of semiconductor devices 115 are then picked up from the dicing tape 108, whereby a plurality of semiconductor devices 115 according to the second embodiment shown in FIG. 19 are manufactured.

The method for manufacturing a semiconductor device according to the second embodiment can provide the same effects as those of the method for manufacturing the semiconductor device 10 according to the first embodiment.

Specifically, the chip stacked body 15 is pasted so that the one surface 37a of the third semiconductor chip 37 having an external size smaller than that of the first and second semiconductor chips 35, 36-1, 36-2, and 36-3 in the X direction is in contact with the adhesive layer 77. The second semiconductor chip 36-3 and the adhesive layer 77 can thus create therebetween a gap where the semi-cured underfill material 17 supplied to the sidewall of the chip stacked body 15 can flow by a capillary action.

This can reduce the number of filling operations of the underfill material 17, which conventionally needs to be two, to one. The steps for manufacturing the semiconductor device 115 can thus be simplified.

The single filling operation of the underfill material 17 can also reduce the heat load on the chip stacked body 15 in the underfill material filling step.

The underfill material 17 is formed after the tape 76 is set to the chip stacked body 15 via the adhesive layer 77 so that one surface 37a of the third semiconductor chip 37 is in contact with the adhesive layer 77. The underfill material 17 is thus prevented from adhering to the fourth bump electrodes 59 which function as the external connection terminals of the chip stacked body 15 and the surface 37a of the third semiconductor chip 37.

In this configuration, the electric connection reliability between the chip stacked body 15 and the fourth semiconductor chip 18 can be improved when the chip stacked body 15 with the first sealing resin 16 is implemented.

It is apparent that the present invention is not limited to the above embodiments, but may be modified and changed without departing from the scope and spirit of the invention.

For example, the first and second embodiments have dealt with the case where the chip stacked body 15 includes a stack of three second semiconductor chips 36-1, 36-2, and 36-3. However, the number of second semiconductor chips constituting the chip stacked body 15 is not limited thereto.

Specifically, the number of second semiconductor chips constituting the chip stacked body 15 may be one or two, or even four or more.

The first and second embodiment have dealt with the first and second semiconductor chips 35, 36-1, 36-2, and 36-3 such that the first to third bump electrodes 44, 48, and 51 are arranged in the center areas of the first and second semiconductor chips 35, 36-1, 36-2, and 36-3. However, the positions of the first to third bump electrodes 44, 48, and 51 are not limited thereto.

For example, the first to third bump electrodes 44, 48, and 51 may be arranged on the peripheral areas of the first and second semiconductor chips 35, 36-1, 36-2, and 36-3.

In addition, while not specifically claimed in the claim section, the applicant reserves the right to include in the claim section of the application at any appropriate time the following methods.

A1. A method for manufacturing a semiconductor device, the method comprising:

preparing a first semiconductor chip that includes a first bump electrode arranged on one surface thereof, a second semiconductor chip that has substantially the same size as that of the first semiconductor chip and includes a second bump electrode arranged on one surface thereof and a third bump electrode arranged on the other surface thereof, and a third semiconductor chip that is smaller in size than the first and second semiconductor chips and includes a fourth bump electrode arranged on one surface thereof and a fifth bump electrode arranged on the other surface thereof;

forming a chip stacked body including the first to third semiconductor chips stacked with one another so that the first bump electrode is electrically connected to the third bump electrode and the second bump electrode is electrically connected to the fifth bump electrode;

pasting the chip stacked body to a tape base via an adhesive layer arranged on one surface of the tape base so that the adhesive layer is in contact with the one surface of the third semiconductor chip;

supplying a semi-cured underfill material to the chip stacked body to fill gaps between the first to third semiconductor chips with the underfill material; and

removing the adhesive layer and the tape base from the chip stacked body.

A2. The method for manufacturing the semiconductor device according to A1, wherein the supplying is performed by filling a gap between the adhesive layer and the second semiconductor chip with the underfill material when filling the gap between the second semiconductor chip and the third semiconductor chip.

A3. The method for manufacturing the semiconductor device according to A1, further comprising curing the underfill material to form a first sealing resin made of the fully-cured underfill material before removing the adhesive layer and the tape base,

wherein the removing the adhesive layer and the tape base includes reducing adhesive power of the adhesive layer, and then horizontally moving the tape base, the adhesive layer, and the chip stacked body in a horizontal direction while vertically moving the tape base and the adhesive layer on the way, thereby stripping the chip stacked body off the adhesive layer.

A4. The method for manufacturing the semiconductor device according to A1, wherein the first semiconductor chip is a greater in thickness than the second and third semiconductor chips.

A5. The method for manufacturing the semiconductor device according to A1, wherein the forming the chip stacked body includes stacking and mounting a plurality of second semiconductor chips between the first semiconductor chip and the third semiconductor chip.

A6. The method for manufacturing the semiconductor device according to A1, further comprising:

preparing a wiring substrate that includes a connection pad arranged on one surface thereof and a land arranged on the other surface thereof; and

electrically connecting the connection pad to the fourth bump electrode by mounting the chip stacked body having the first sealing resin on the wiring substrate.

A7. The method for manufacturing the semiconductor device according to A1, further comprising:

preparing a wiring substrate that includes a connection pad arranged on one surface thereof and a land arranged on the other surface thereof;

preparing a fourth semiconductor chip that includes a sixth bump electrode arranged on one surface thereof and a seventh bump electrode arranged on the other surface thereof;

electrically connecting the connection pad to the sixth bump electrode by mounting the fourth semiconductor chip on the wiring substrate; and

after the mounting of the fourth semiconductor chip on the wiring substrate, mounting the chip stacked body having the first sealing resin on the fourth semiconductor chip so that the fourth bump electrode is electrically connected to the seventh bump electrode.

What is claimed is:

1. A semiconductor device comprising:
a first semiconductor chip including a first surface and a second surface opposite to the first surface;
a second semiconductor chip stacked over the second surface of the first semiconductor chip, and the second semiconductor chip being larger in size than the first semiconductor chip; and
a first sealing resin covering the first and second semiconductor chips so that the first surface exposes from the first sealing resin,
wherein a first width of the first sealing resin that is around the first semiconductor chip is larger than a second width of the first sealing resin that is around the second semiconductor chip.

2. The semiconductor device as claimed in claim 1, further comprising a third semiconductor chip stacked over the second semiconductor chip, wherein
the third semiconductor chip has substantially the same size as the second semiconductor chip, and
the second width of the first sealing resin is larger than a third width of the first sealing resin that is around the third semiconductor chip.

3. The semiconductor device as claimed in claim 2, wherein the second and third semiconductor chips are memory chips and the first semiconductor chip is a control chip that controls an operation of the second and third semiconductor chips.

4. The semiconductor device as claimed in claim 2, wherein the second semiconductor chip including:
a semiconductor substrate; and
a through electrode penetrating through the semiconductor substrate, one end of the through electrode being connected to the first semiconductor chip, and the other end of the through electrode being connected to the third semiconductor chip.

5. The semiconductor device as claimed in claim 1, wherein
the first sealing resin has first and second side surfaces opposite to each other,
the first side surface of the first sealing resin has a first angle with respect to the first and second surfaces of the first semiconductor chip,
the second side surface of the first sealing resin has a second angle with respect to the first and second surfaces of the first semiconductor chip, and
the first angle is greater than the second angle.

6. The semiconductor device as claimed in claim 1, further comprising:
a wiring substrate on which the first and second semiconductor chips are mounted;
an adhesive member provided between the first surface of the first semiconductor chip and the wiring substrate.

7. The semiconductor device as claimed in claim 6, further comprising a second sealing resin formed on the wiring substrate so that the first and second semiconductor chips, the first sealing resin and the adhesive member are covered with the second sealing resin.

8. The semiconductor device as claimed in claim 1, further comprising:
a wiring substrate;
a semiconductor substrate mounted on the wiring substrate, the first and second semiconductor chips being mounted on the semiconductor substrate;
an adhesive member provided between the first surface of the first semiconductor chip and the semiconductor substrate;
a second sealing resin provided between the wiring substrate and the semiconductor substrate; and
a third sealing resin formed on the wiring substrate so that the first and second semiconductor chips, the semiconductor substrate, the first and second sealing resins and the adhesive member are covered with the third sealing resin.

9. A semiconductor device comprising:
a first sealing resin having a substantially trapezoidal shape in side view;
a first semiconductor chip including a first surface and a second surface opposite to the first surface, the first semiconductor chip being embedded in the first sealing resin so that the first surface exposes from a longer side of the substantially trapezoidal shape of the first sealing resin; and
a second semiconductor chip stacked over the second surface of the first semiconductor chip and embedded in the first sealing resin, and the second semiconductor chip is larger in size than the first semiconductor chip.

10. The semiconductor device as claimed in claim 9, further comprising:
a wiring substrate stacked over the first surface of the first semiconductor chip; and
an adhesive member provided between the first surface of the first semiconductor chip and the wiring substrate.

11. The semiconductor device as claimed in claim 10, wherein the adhesive member is further provided between the longer side of the substantially trapezoidal shape of the first sealing resin and the wiring substrate.

12. The semiconductor device as claimed in claim 10, further comprising a second sealing resin formed on the wiring substrate so that the first and second semiconductor chips, the first sealing resin and the adhesive member are covered with the second sealing resin.

13. The semiconductor device as claimed in claim 10, wherein the first semiconductor chip includes a semiconductor substrate and a through electrode penetrating through the semiconductor substrate, the through electrode is electrically connected the second semiconductor chip to the wiring substrate.

14. The semiconductor device as claimed in claim 9, wherein the second semiconductor chip is a memory chip and the first semiconductor chip is a control chip that controls an operation of the second semiconductor chip.

15. The semiconductor device as claimed in claim 9, further comprising a third semiconductor chip stacked over the second semiconductor chip and embedded in the first sealing resin, and the third semiconductor chip is substantially equal in size to the second semiconductor chip.

16. A semiconductor device comprising:
a first semiconductor chip including a first surface and a second surface opposite to the first surface;
a second semiconductor chip stacked over the second surface of the first semiconductor chip, and the second semiconductor chip being larger in size than the first semiconductor chip; and
a sealing resin covering the first and second semiconductor chips, the sealing resin including a bottom surface exposing the first surface of the semiconductor chip, a total area including an area of the first surface of the first semiconductor chip and an area of the bottom surface of the sealing resin, and the total area is larger in area than the second semiconductor chip.

17. The semiconductor device as claimed in claim 16, further comprising a wiring substrate stacked over the first surface of the first semiconductor chip so that the bottom surface of the sealing resin is apart from the wiring substrate.

18. The semiconductor device as claimed in claim 17, further comprising an adhesive member provided between the bottom surface of the sealing resin and the wiring substrate.

19. The semiconductor device as claimed in claim 17, wherein the first semiconductor chip includes a semiconductor substrate and a through electrode penetrating through the semiconductor substrate, the through electrode is electrically connected the second semiconductor chip to the wiring substrate.

20. The semiconductor device as claimed in claim 17, further comprising a semiconductor substrate provided between the first semiconductor chip and the wiring substrate, and the semiconductor substrate is larger in area than the total area.
